(19) United States
(12) Patent Application Publication
(10) Pub. No.: US 2024/0032362 A1
(43) Pub. Date: Jan. 25, 2024

(54) DISPLAY DEVICE

(71) Applicant: LG Display Co., Ltd., Seoul (KR)

(72) Inventors: ByungHyun LEE, Paju-si (KR); SunHwa LEE, Goyang-si (KR); JongBeom LEE, Paju-si (KR); Soyi LEE, Paju-si (KR); Seeun KIM, Seoul (KR)

(21) Appl. No.: 18/356,159

(22) Filed: Jul. 20, 2023

(30) Foreign Application Priority Data
Jul. 25, 2022 (KR) 10-2022-0091888

(51) Int. Cl. H10K 59/131; H10K 77/10; H10K 59/121

(52) U.S. Cl. CPC H10K 59/131; H10K 77/111; H10K 59/1213

(57) ABSTRACT

A display device includes a lower substrate including an active area and a non-active area and configured to be stretchable, a pattern layer disposed on the lower substrate and including a plurality of second plate patterns and a plurality of second line patterns formed in the non-active area, and power supplies formed on the plurality of second plate patterns. The power supplies include a first power pattern and a second power pattern disposed on different layers. Adjacent power supplies among the plurality of power supplies are electrically connected to each other through a power line. Each of the first power pattern and the second power pattern includes at least one plate-shaped electrode.

### CROSS-REFERENCE TO RELATED APPLICATION

This application claims the benefit of and priority to Korean Patent Application No. 10-2022-0091888 filed on Jul. 25, 2022, in the Republic of Korea, the entire contents of which are hereby expressly incorporated by reference into the present application.

### BACKGROUND

### Technical Field

The present disclosure relates to a display device, and more particularly, to a stretchable display device.

### Description of the Related Art

Display devices used for a computer monitor, a TV, a mobile phone, and the like include an organic light emitting display (OLED) that emits light by itself, a liquid crystal display (LCD) that requires a separate light source, and the like.

Such display devices are being applied to more and more various fields of application including not only a computer monitor and a TV, but personal mobile devices, and thus, display devices having a reduced volume and weight while having a wide active area are being studied.

Recently, a display device that is manufactured to be stretchable in a specific direction and changeable into various shapes by forming a display unit, lines, and the like on a flexible substrate such as plastic that is a flexible material has received considerable attention as a next-generation display device.

### BRIEF SUMMARY

An aspect of the present disclosure is to provide a display device in which lines are not damaged even when repeatedly stretched.

Another aspect of the present disclosure is to provide a display device in which all areas thereof can be biaxially stretched.

Still another aspect of the present disclosure is to provide a display device capable of preventing line from being torn off during a lift-off process.

Still another aspect of the present disclosure is to provide a display device capable of preventing a drop in driving voltage.

Technical benefits of the present disclosure are not limited to the above-mentioned benefits, and other benefits, which are not mentioned above, can be clearly understood by those skilled in the art from the following descriptions.

A display device according to an exemplary embodiment of the present disclosure includes a lower substrate including an active area and a non-active area and configured to be stretchable; a pattern layer disposed on the lower substrate and including a plurality of first plate patterns and a plurality of first line patterns formed in the active area and a plurality of second plate patterns and a plurality of second line patterns formed in the non-active area; a plurality of pixels formed on the plurality of first plate patterns; a plurality of first connection lines connecting the plurality of pixels; gate drivers formed on the plurality of second plate patterns; power supplies formed on the plurality of second plate patterns; a plurality of second connection lines disposed in the non-active area; and an upper substrate covering the gate drivers, the power supplies, and the plurality of pixels and configured to be stretchable, wherein the non-active area includes a first area located outside the active area, a second area located outside the first area and having the plurality of gate drivers disposed therein, and a third area located outside the second area and having the plurality of power supplies disposed therein, and wherein the plurality of second connection lines disposed in the first area are in contact with metal patterns disposed on a different layer from the plurality of second connection lines through anchor holes.

A display device according to another exemplary embodiment of the present disclosure includes a flexible substrate, a plurality of rigid patterns formed on the flexible substrate, a plurality of pixels formed on a plurality of first plate patterns spaced apart from each other among the plurality of rigid patterns, and power supplies formed on portions of a plurality of second plate patterns spaced apart from each other among the plurality of rigid patterns, wherein the power supplies are configured to include power blocks spaced apart from each other in a first direction and a second direction and supplying a driving voltage to a plurality of pixels.

A display device according to still another exemplary embodiment of the present disclosure includes a lower substrate including an active area and a non-active area and configured to be stretchable; and a pattern layer disposed on the lower substrate and including a plurality of first plate patterns and a plurality of first line patterns formed in the active area and a plurality of second plate patterns and a plurality of second line patterns formed in the non-active area. The display device further includes a plurality of pixels formed on the plurality of first plate patterns; a plurality of first connection lines connecting the plurality of pixels; gate drivers formed on the plurality of second plate patterns; power supplies formed on the plurality of second plate patterns; a plurality of second connection lines disposed in the non-active area; and an upper substrate covering the gate drivers, the power supplies, and the plurality of pixels and configured to be stretchable. The non-active area includes a first area located outside the active area, a second area located outside the first area and having the plurality of gate drivers disposed therein, and a third area located outside the second area and having the plurality of power supplies disposed therein, wherein the plurality of power supplies include a first power pattern and a second power pattern disposed on different layers, wherein adjacent power supplies among the plurality of power supplies are electrically connected to each other through a power line, and wherein each of the first power pattern and the second power pattern includes at least one plate-shaped electrode.

A display device according to still another exemplary embodiment of the present disclosure includes a plurality of first plate patterns and a plurality of second plate patterns on a substrate; a plurality of line patterns connected to the second plate patterns; power lines on the line patterns; a first power pattern configured to include at least one layer on the second plate pattern; an insulating layer on the first power pattern; and a second power pattern configured to include at least one layer on the insulating layer, wherein the power lines are directly connected to the second power pattern, wherein the second power pattern further includes at least one connection portion that opens the insulating layer, and wherein the power lines are electrically connected to the first power pattern through at least one contact hole in the open insulating layer.

Other detailed matters of the exemplary embodiments are included in the detailed description and the drawings.

According to the present disclosure, by forming anchor holes in buffer lines, stretching reliability of a display device can be stably secured.

According to the present disclosure, a display device cannot be damaged during a lift off process by fixing buffer lines through anchor holes.

According to the present disclosure, since a non-active area is stretched in a biaxial direction, usability of the display device can be improved.

According to the present disclosure, a power supply can include an additional power block electrically connected between power blocks, thereby reducing or minimizing a drop in driving voltage.

The effects according to the present disclosure are not limited to the contents exemplified above, and more various effects are included in the present specification.

### BRIEF DESCRIPTION OF THE SEVERAL VIEWS OF THE DRAWINGS

FIG. 1 is a plan view of a display device according to an exemplary embodiment of the present disclosure.

FIG. 2 is an enlarged plan view of an active area of the display device according to an exemplary embodiment of the present disclosure.

FIG. 3 is a cross-sectional view taken along cutting line III-III′ shown in FIG. 2.

FIG. 4 is a cross-sectional view taken along cutting line IV-IV′ shown in FIG. 2.

FIG. 5 is a cross-sectional view taken along cutting line V-V′ shown in FIG. 2.

FIG. 6 is a circuit diagram of a sub-pixel of the display device according to an exemplary embodiment of the present disclosure.

FIG. 7 is an enlarged plan view of a non-active area of the display device according to an exemplary embodiment of the present disclosure.

FIG. 8 is an enlarged plan view of a first area of the display device according to an exemplary embodiment of the present disclosure.

FIG. 9 is a cross-sectional view taken along cutting line IX-IX′ shown in FIG. 8.

FIG. 10 is an enlarged plan view of a third area of the display device according to an exemplary embodiment of the present disclosure.

FIG. 11 is a cross-sectional view taken along cutting line XI-XI′ shown in FIG. 10.

FIG. 12 is a cross-sectional view taken along cutting line XI-XI′ shown in FIG. 10 according to another exemplary embodiment of the present disclosure.

FIG. 13 is a cross-sectional view taken along cutting line XI-XI′ shown in FIG. 10 according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly” is not used.

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

When the term ‘connect’ or ‘contact’ mentioned in the present disclosure is used, one or more parts may be positioned between two parts and the two parts can be connected or in contact with each other unless the term is used with the term ‘immediately’ or ‘directly.’

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

A display device according to an exemplary embodiment of the present disclosure is a display device capable of displaying an image even if it is bent or stretched, and may also be referred to as a stretchable display device or a flexible display device. The display device may have higher flexibility and stretchability than conventional, typical display devices. Accordingly, a user can bend or stretch the display device, and a shape of the display device can be freely changed according to the user's manipulation. For example, when the user grabs and pulls an end of the display device, the display device may be stretched in a pulling direction by the user. If the user places the display device on an uneven outer surface, the display device can be disposed to be bent according to a shape of the outer surface. When force applied by the user is removed, the display device can return to an original shape thereof.

### Stretchable Substrate and Pattern Layer

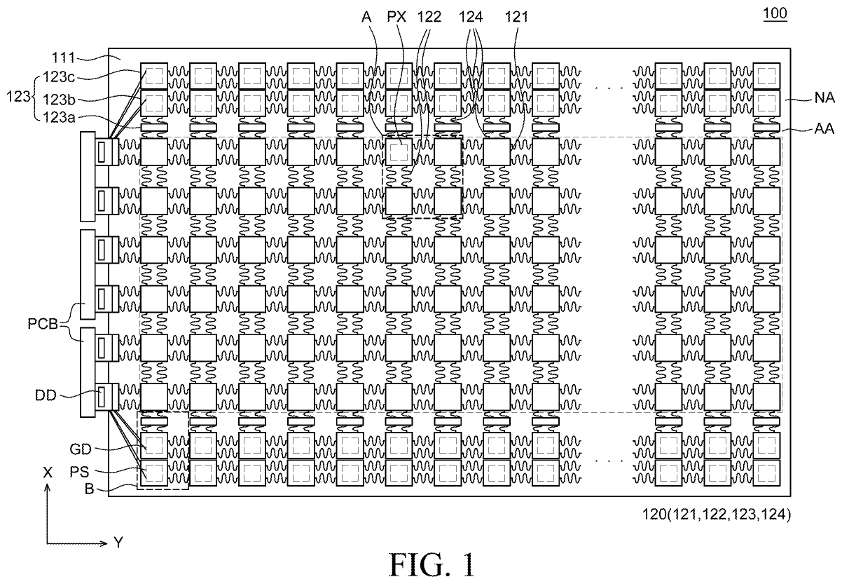

FIG. 1 is a plan view of a display device according to an exemplary embodiment of the present disclosure.

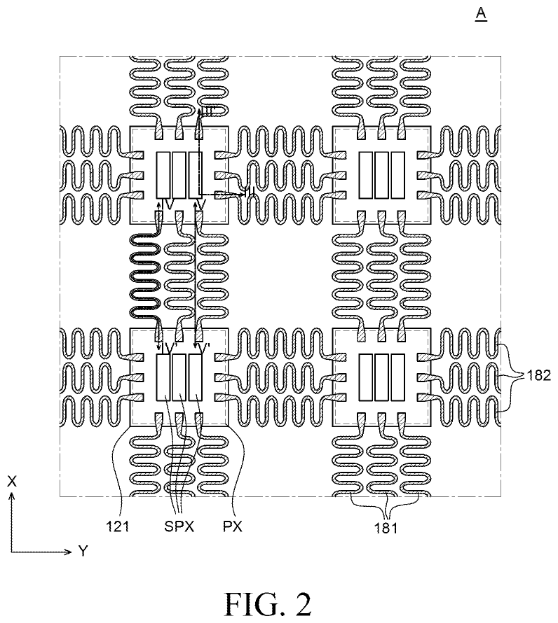

FIG. 2 is an enlarged plan view of an active area of the display device according to an exemplary embodiment of the present disclosure. Specifically, FIG. 2 is an enlarged plan view of area A shown in FIG. 1.

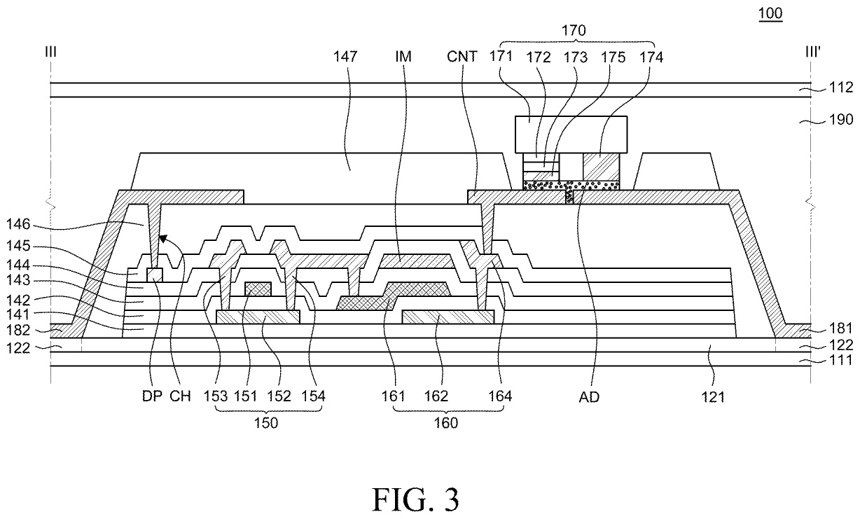

FIG. 3 is a cross-sectional view taken along cutting line shown in FIG. 2.

Referring to FIG. 1, a display device 100 according to an exemplary embodiment of the present disclosure may include a lower substrate 111, a pattern layer 120, a plurality of pixels PX, gate drivers GD, data drivers DD, and power supplies PS. And, referring to FIG. 3, the display device 100 according to an exemplary embodiment of the present disclosure may further include a filling layer 190 and an upper substrate 112.

The lower substrate 111 is a substrate for supporting and protecting various components of the display device 100. In addition, the upper substrate 112 is a substrate for covering and protecting various components of the display device 100. That is, the lower substrate 111 is a substrate that supports the pattern layer 120 on which the pixels PX, the gate drivers GD, and the power supplies PS are formed. In addition, the upper substrate 112 is a substrate that covers the pixels PX, the gate drivers GD, and the power supplies PS.

Each of the lower substrate 111 and the upper substrate 112 is a ductile substrate and may be formed of an insulating material that can be bent or stretched. For example, each of the lower substrate 111 and the upper substrate 112 may be formed of silicone rubber such as polydimethylsiloxane (PDMS) or an elastomer such as polyurethane (PU), polytetrafluoroethylene (PTFE) or the like, and thus, may have flexible properties. In addition, materials of the lower substrate 111 and the upper substrate 112 may be the same, but are not limited thereto and may be variously modified.

Each of the lower substrate 111 and the upper substrate 112 is a ductile substrate and may be reversibly expandable and contractible. Accordingly, the lower substrate 111 may be referred to as a lower stretchable substrate, a lower flexible substrate, a lower extendable substrate, a lower ductile substrate, a first stretchable substrate, a first flexible substrate, a first extendable substrate, or a first ductile substrate, and the upper substrate 112 may be referred to as an upper stretchable substrate, an upper flexible substrate, an upper extendable substrate, an upper ductile substrate, a second stretchable substrate, a second flexible substrate, a second extendable substrate, or a second ductile substrate. Further, moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a time at which an object that is stretched is broken or cracked. A thickness of the lower substrate 111 may be 10 μm to 1 mm, but is not limited thereto.

The lower substrate 111 may have an active area AA and a non-active area NA surrounding the active area AA.

The active area AA is an area in which an image is displayed on the display device 100. The plurality of pixels PX are disposed in the active area AA. In addition, each of the pixels PX may include a display element and various driving elements for driving the display element. The various driving elements may mean at least one thin film transistor TFT and a capacitor, but are not limited thereto. In addition, each of the plurality of pixels PX may be connected to various lines. For example, each of the plurality of pixels PX may be connected to various lines such as gate lines, data lines, high potential power lines, low potential power lines, reference voltage lines, and the like.

The non-active area NA is an area in which an image is not displayed. The non-active area NA may be an area that is disposed adjacent to the active area AA and surrounds the active area AA. However, the present disclosure is not limited thereto, and the non-active area NA corresponds to an area of the lower substrate 111 excluding the active area AA and may be changed and separated into various shapes. Components for driving the plurality of pixels PX disposed in the active area AA are disposed in the non-active area NA. The gate drivers GD and power supplies PS may be disposed in the non-active area NA. In addition, a plurality of pads that are connected to the gate drivers GD and the data drivers DD may be disposed in the non-active area NA, and each of the pads may be connected to each of the plurality of pixels PX in the active area AA.

On the lower substrate 111, the pattern layer 120 formed of a plastic material having flexibility lower than the lower substrate 111 may be disposed. For example, the pattern layer 120 may be formed of polyimide (PI), polyacrylate, polyacetate, or the like.

The pattern layer 120 may include a plurality of first plate patterns 121 and a plurality of first line patterns 122 that are disposed in the active area AA and a plurality of second plate patterns 123 and a plurality of second line patterns 124 that are disposed in the non-active area NA.

The plurality of first plate patterns 121 may be disposed in the active area AA of the lower substrate 111. The plurality of pixels PX are formed on the plurality of first plate patterns 121. In addition, the plurality of second plate patterns 123 are disposed in the non-active area NA of the lower substrate 111. In addition, the gate drivers GD and the power supplies PS are formed on the plurality of second plate patterns 123.

The plurality of first plate patterns 121 and the plurality of second plate patterns 123 as described above may be disposed in the form of islands that are spaced apart from each other. Each of the plurality of first plate patterns 121 and the plurality of second plate patterns 123 may be individually separated. Accordingly, the plurality of first plate patterns 121 and the plurality of second plate patterns 123 may be referred to as first island patterns and second island patterns, or first individual patterns and second individual patterns. The first plate patterns 121 that are disposed to be spaced apart from each other may be connected by the first line patterns 122. Also, in the non-active area NA, the second plate patterns 123 that are disposed to be spaced apart from each other may be connected by the second line patterns 124.

Specifically, the plurality of second plate patterns 123 disposed in the non-active area NA include a plurality of first sub-plate patterns 123a in which anchor holes are disposed, a plurality of second sub-plate patterns 123b in which the gate drivers GD are disposed, and a plurality of third sub-plate patterns 123c in which the power supplies PS are disposed.

More specifically, as shown in FIG. 1, the plurality of first sub-plate patterns 123a may be disposed adjacent to the active area AA in a first direction X and spaced apart from each other in a second direction Y. That is, the first sub-plate patterns 123a may be disposed on both sides of the active area AA in the first direction X. However, the present disclosure is not limited thereto, and the first sub-plate patterns 123a may be disposed only on one side of the active area AA in the first direction X. Also, anchor holes for binding the plurality of connection lines may be disposed on the plurality of first sub-plate patterns 123a.

Also, the plurality of second sub-plate patterns 123b may be disposed adjacent to the plurality of first sub-plate patterns 123a in the first direction X and spaced apart from each other in the second direction Y. That is, the plurality of second sub-plate patterns 123b may be disposed on both sides of the plurality of first sub-plate patterns 123a in the first direction X. However, the present disclosure is not limited thereto, and the second sub-plate patterns 123b may be disposed only on one sides of the plurality of first sub-plate patterns 123a.

In addition, the gate drivers GD may be mounted on the plurality of second sub-plate patterns 123b. The gate drivers GD may be formed on the second sub-plate patterns 123b in a gate in panel (GIP) method when various components on the first plate patterns 121 are manufactured. Accordingly, various circuit components constituting the gate drivers GD such as various transistors, capacitors, and lines may be disposed on the plurality of second sub-plate patterns 123b. However, the present disclosure is not limited thereto, and the gate drivers GD may be mounted in a chip on film (COF) method.

Also, the plurality of third sub-plate patterns 123c may be disposed adjacent to the plurality of second sub-plate patterns 123b in the first direction X and spaced apart from each other in the second direction Y. That is, the plurality of third sub-plate patterns 123c may be disposed on both sides of the plurality of second sub-plate patterns 123b in the first direction X. However, the present disclosure is not limited thereto, and the third sub-plate patterns 123c may be disposed only on one sides of the plurality of second sub-plate patterns 123b in the first direction X. In addition, the power supplies PS may be mounted on the plurality of third sub-plate patterns 123c. The power supplies PS may be formed on the third sub-plate patterns 123c as a plurality of power blocks patterned when manufacturing various components on the first plate patterns 121. Accordingly, the power blocks disposed on different layers may be disposed on the third sub-plate patterns 123c.

Referring to FIG. 1, sizes of the plurality of first sub-plate patterns 123a may be smaller than those of the plurality of first plate patterns 121. Specifically, the size of each of the plurality of first sub-plate patterns 123a may be smaller than the size of each of the plurality of first plate patterns 121. As described above, anchor holes AH are disposed in respective first sub-plate pattern of the plurality of respective first sub-plate patterns 123a. Since areas occupied by the anchor holes AH are smaller than areas occupied by the pixels PX, the size of each of the plurality of first sub-plate patterns 123a may be smaller than the size of each of the plurality of first plate patterns 121.

Also, sizes of the plurality of second sub-plate patterns 123b may be greater than those of the plurality of first plate patterns 121. Specifically, the size of each of the plurality of second sub-plate patterns 123b may be greater than that of each of the plurality of first plate patterns 121. As described above, the gate driver GD may be disposed on each of the plurality of second sub-plate patterns 123b, and one stage of the gate driver GD may be disposed on each of the plurality of second sub-plate patterns 123b. Accordingly, since an area occupied by various circuit components constituting one stage of the gate driver GD is relatively greater than an area occupied by the pixel PX, the size of each of the plurality of second sub-plate patterns 123b may be greater than the size of each of the first plate patterns 121.

In FIG. 1, the plurality of second plate patterns 123 are illustrated as being disposed on both sides in the first direction X in the non-active area NA, but the present disclosure is not limited thereto, and the plurality of second plate patterns 123 may be disposed in any area of the non-active area NA. In addition, although the plurality of first plate patterns 121 and the plurality of second plate patterns 123 are illustrated in quadrangular shapes, the present disclosure is not limited thereto, and the plurality of first plate patterns 121 and the plurality of second plate patterns 123 are changeable in various shapes.

Referring to FIGS. 1 and 3, the pattern layer 120 may further include the plurality of first line patterns 122 disposed in the active area AA and the plurality of second line patterns 124 disposed in the non-active area NA.

The plurality of first line patterns 122 may be disposed in the active area AA. Also, the plurality of first line patterns 122 are patterns connecting the first plate patterns 121 adjacent to each other and may be referred to as first connection patterns. That is, the plurality of first line patterns 122 are disposed between the plurality of first plate patterns 121.

The plurality of second line patterns 124 may be disposed in the non-active area NA. Also, the plurality of second line patterns 124 may connect the first plate patterns 121 and the second plate patterns 123 adjacent to each other and connect the second plate patterns 123 adjacent to each other. For example, the plurality of second line patterns 124 may connect the first plate patterns 121 located at an edge of the active area AA and the second plate patterns 123 disposed adjacent to the first plate patterns 121 in the non-active area NA. Also, the plurality of second line patterns 124 may be patterns connecting the plurality of second plate patterns 123 adjacent to each other. Accordingly, the plurality of second line patterns 124 may be referred to as second connection patterns. That is, the plurality of second line patterns 124 are disposed between the first plate patterns 121 and the second plate patterns 123 that are adjacent to each other. The plurality of second line patterns 124 are disposed between the plurality of second plate patterns 123 that are adjacent to each other.

Referring to FIG. 1, the plurality of first line patterns 122 and the plurality of second line patterns 124 have a wavy shape. For example, the plurality of first line patterns 122 and the plurality of second line patterns 124 may have a sine wave shape. However, the shapes of the plurality of first line patterns 122 and the plurality of second line patterns 124 are not limited thereto. For example, the plurality of first line patterns 122 and the plurality of second line patterns 124 may extend in a zigzag manner. Alternatively, shapes of the plurality of first line patterns 122 and the plurality of the second line patterns 124 may have various shapes, such as shapes in which a plurality of rhombus-shaped substrates are extended by being connected at vertices thereof. The numbers and shapes of the plurality of first line patterns 122 and the second line patterns 124 illustrated in FIG. 1 are exemplarily provided, and the numbers and shapes of the plurality of first line patterns 122 and the second line patterns 124 may be variously changed according to design.

In addition, the plurality of first plate patterns 121, the plurality of first line patterns 122, the plurality of second plate patterns 123, and the plurality of second line patterns 124 are rigid patterns. That is, the plurality of first plate patterns 121, the plurality of first line patterns 122, the plurality of second plate patterns 123, and the plurality of second line patterns 124 may be rigid compared to the lower substrate 111 and the upper substrate 112. That is, moduli of elasticity of the plurality of first plate patterns 121, the plurality of first line patterns 122, the plurality of second plate patterns 123, and the plurality of second line patterns 124 may be higher than a modulus of elasticity of the lower substrate 111. The modulus of elasticity is a parameter representing a rate of deformation against a stress applied to the substrate. When the modulus of elasticity is relatively high, hardness may be relatively high. Accordingly, the plurality of first plate patterns 121, the plurality of first line patterns 122, the plurality of second plate patterns 123, and the plurality of second line patterns 124 may be referred to as a plurality of first rigid patterns, a plurality of second rigid patterns, a plurality of third rigid patterns, and a plurality of fourth rigid patterns, respectively. The moduli of elasticity of the plurality of first plate patterns 121, the plurality of first line patterns 122, the plurality of second plate patterns 123, and the plurality of second line patterns 124 may be 1000 times higher than the moduli of elasticity of the lower substrate 111 and the upper substrate 112, but the present disclosure is not limited thereto.

The plurality of first plate patterns 121, the plurality of first line patterns 122, the plurality of second plate patterns 123, and the plurality of second line patterns 124 that are a plurality of rigid substrates may be formed of a plastic material having flexibility that is lower than that of the lower substrate 111 and the upper substrate 112. For example, the plurality of first plate patterns 121, the plurality of first line patterns 122, the plurality of second plate patterns 123, and the plurality of second line patterns 124 may be formed of, for example, polyimide (PI), polyacrylate or polyacetate. In this case, the plurality of first plate patterns 121, the plurality of first line patterns 122, the plurality of second plate patterns 123, and the plurality of second line patterns 124 may be formed of the same material, but they are not limited thereto and may be formed of different materials.

In some embodiments, the lower substrate 111 may be defined as including a plurality of first lower patterns and second lower patterns. The plurality of first lower patterns may be disposed in areas of the lower substrate 111 that overlap the plurality of first plate patterns 121 and the plurality of second plate patterns 123. The second lower patterns may be disposed in an area other than an area where the plurality of first plate patterns 121 and the plurality of second plate patterns 123 are disposed, or may be disposed in an entire area of the display device 100.

Also, the upper substrate 112 may be defined as including a plurality of first upper patterns and second upper patterns. The plurality of first upper patterns may be disposed in areas of the upper substrate 112 that overlap the plurality of first plate patterns 121 and the plurality of second plate patterns 123. The second upper patterns may be disposed in an area other than the area where the plurality of first plate patterns 121 and the plurality of second plate patterns 123 are disposed, or may be disposed in the entire area of the display device 100.

In this case, moduli of elasticity of the plurality of first lower patterns and first upper patterns may be higher than moduli of elasticity of the second lower patterns and the second upper patterns. For example, the plurality of first lower patterns and the first upper patterns may be formed of the same material as the plurality of first plate patterns 121 and the plurality of second plate patterns 123, and the second lower patterns and the second upper patterns may be formed of a material having a modulus of elasticity lower than those of the plurality of first plate patterns 121 and the plurality of second plate patterns 123.

That is, the first lower pattern and the first upper pattern may be formed of polyimide (PI), polyacrylate, polyacetate, or the like, and the second lower pattern and the second upper pattern may be formed of silicon rubber such as polydimethylsiloxane (PDMS) or an elastomer such as polyurethane (PU), polytetrafluoroethylene (PTFE) or the like.

### Non-Active Area Driving Element

The gate drivers GD are components which supply a gate voltage to the plurality of pixels PX disposed in the active area AA. The gate drivers GD include a plurality of stages formed on the second sub-plate patterns 123b of the plurality of second plate patterns 123 and respective stages of the gate drivers GD may be electrically connected to each other through a plurality of gate connection lines. Accordingly, a gate voltage output from any one of stages may be transmitted to another stage. Further, the respective stages may sequentially supply the gate voltage to the plurality of pixels PX connected to the respective stages.

The power supplies PS may be connected to the gate drivers GD and supply a gate driving voltage and a gate clock voltage. Further, the power supplies PS may be connected to the plurality of pixels PX and supply a pixel driving voltage to each of the plurality of pixels PX. Also, the power supplies PS may be formed on the third sub-plate patterns 123c of the plurality of second plate patterns 123. That is, the power supplies PS may be formed on the second plate patterns 123 to be adjacent to the gate drivers GD. Also, the respective power supplies PS formed on the plurality of third sub-plate patterns 123c may be electrically connected to the gate drivers GD and the plurality of pixels PX. That is, the plurality of power supplies PS formed on the plurality of third sub-plate patterns 123c may be connected by gate power supply connection lines and pixel power supply connection lines. Accordingly, each of the plurality of power supplies PS may supply a gate driving voltage, a gate clock voltage, and a pixel driving voltage.

The printed circuit board PCB is a component which transmits signals and voltages for driving the display element from a control unit to the display element. Accordingly, the printed circuit board PCB may also be referred to as a driving substrate. A control unit such as an IC chip or a circuit may be mounted on the printed circuit board PCB. Further, a memory, a processor or the like may be mounted on the printed circuit board PCB. Further, the printed circuit board PCB provided in the display device 100 may include a stretchable area and a non-stretchable area to secure stretchability. Also, on the non-stretchable area, an IC chip, a circuit, a memory, a processor and the like may be mounted, and in the stretchable area, lines that are electrically connected to the IC chip, the circuit, the memory and the processor may be disposed.

The data driver DD is a component which supplies a data voltage to the plurality of pixels PX disposed in the active area AA. The data driver DD may be configured in a form of an IC chip and thus, may also be referred to as a data integrated circuit D-IC. Further, the data driver DD may be mounted on the non-stretchable area of the printed circuit board PCB. That is, the data driver DD may be mounted on the printed circuit board PCB in a form of a chip on board (COB). Although in FIG. 1, it is illustrated that the data driver DD is mounted in a chip on board (COB) manner, the present disclosure is not limited thereto and the data driver DD may be mounted in a chip on film (COF), a chip on glass (COG), a tape carrier package (TCP) manner, or the like.

Also, although it is illustrated in FIG. 1 that one data driver DD is disposed to correspond to a line of the first plate patterns 121 disposed in the active area AA, the present disclosure is not limited thereto. That is, one data driver DD may be disposed to correspond to a plurality of columns of the first plate patterns 121.

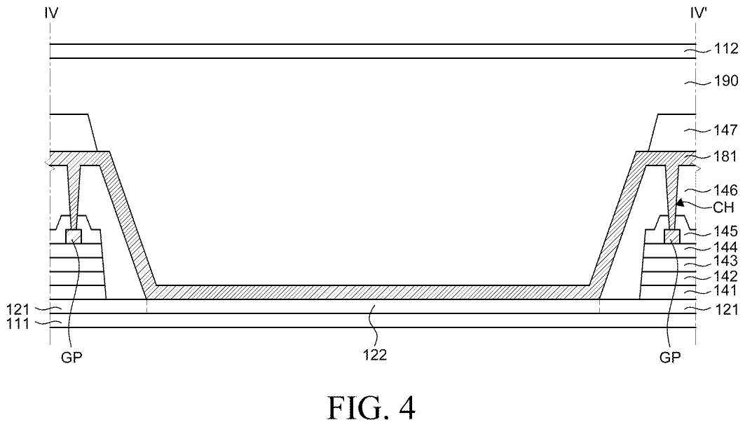

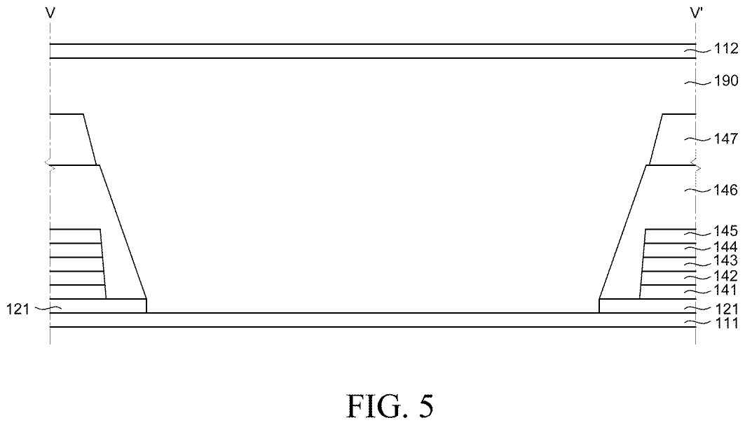

Hereinafter, FIGS. 4 and 5 are referred together for a more detailed description of the active area AA of the display device 100 according to an exemplary embodiment of the present disclosure.

### Planar and Cross-Sectional Structures of Active Area

FIG. 4 is a cross-sectional view taken along cutting line IV-IV′ shown in FIG. 2.

FIG. 5 is a cross-sectional view taken along cutting line V-V′ shown in FIG. 2.

FIGS. 1 to 3 are referred together for convenience of explanation.

Referring to FIGS. 1 and 2, the plurality of first plate patterns 121 are disposed on the lower substrate 111 in the active area AA. The plurality of first plate patterns 121 are disposed to be spaced apart from each other on the lower substrate 111. For example, the plurality of first plate patterns 121 may be disposed in a matrix form on the lower substrate 111 as illustrated in FIG. 1, but are not limited thereto.

Referring to FIGS. 2 and 3, the pixels PX including a plurality of sub-pixels SPX are disposed on the first plate patterns 121. Also, each of the sub-pixels SPX may include a light emitting element 170, which is a display element, and a driving transistor 160 and a switching transistor 150 for driving the light emitting element 170. However, the display element in the sub-pixel SPX is not limited to the light emitting element and may be an organic light emitting diode. Further, the plurality of sub-pixels SPX may include a red sub-pixel, a green sub-pixel, and a blue sub-pixel, but are not limited thereto. Colors of the plurality of sub-pixels SPX may be variously changed as needed.

The plurality of sub-pixels SPX may be connected to a plurality of pixel connection lines 181 and 182. That is, the plurality of sub-pixels SPX may be electrically connected to first pixel connection lines 181 extended in the first direction X. Also, the plurality of sub-pixels SPX may be electrically connected to second pixel connection lines 182 extended in a second direction Y.

Meanwhile, the plurality of pixel connection lines 181 and 182 disposed in the active area AA may be referred to as first connection lines, and buffer lines, gate connection lines, or power lines disposed in the non-active area NA may be referred to as second connection lines.

Hereinafter, a cross-sectional structure of the active area AA will be described in detail with reference to FIG. 3.

Referring to FIG. 3, a plurality of inorganic insulating layers are disposed on the plurality of first plate patterns 121. For example, the plurality of inorganic insulating layers may include a buffer layer 141, a gate insulating layer 142, a first interlayer insulating layer 143, a second interlayer insulating layer 144, and a passivation layer 145. However, the present disclosure is not limited thereto. Various inorganic insulating layers may be further disposed on the plurality of first plate patterns 121. One or more of the buffer layer 141, the gate insulating layer 142, the first interlayer insulating layer 143, the second interlayer insulating layer 144, and the passivation layer 145 which are inorganic insulating layers may be omitted therefrom.

Specifically, the buffer layer 141 is disposed on the plurality of first plate patterns 121. The buffer layer 141 is formed on the plurality of first plate patterns 121 to protect various components of the display device 100 against permeation of moisture (H₂O), oxygen (O₂) or the like from the outside of the lower substrate 111 and the plurality of first plate patterns 121. The buffer layer 141 may be formed of an insulating material. For example, the buffer layer 141 may be formed as a single layer or multiple layers of silicon nitride (SiNx), silicon oxide (SiOx), silicon oxynitride (SiON), or the like. However, the buffer layer 141 may be omitted depending on a structure or characteristics of the display device 100.

In the active area AA, the buffer layer 141 may be formed only in an area where the lower substrate 111 overlaps the plurality of first plate patterns 121. As described above, the buffer layer 141 may be formed of an inorganic material. Thus, the buffer layer 141 may be easily damaged, such as easily cracked, while the display device 100 is stretched. Therefore, in the active area AA, the buffer layer 141 may not be formed in areas between the plurality of first plate patterns 121. The buffer layer 141 may be patterned into shapes of the plurality of first plate patterns 121 and formed only on upper portions of the plurality of first plate patterns 121.

In addition, in the non-active area AA, the buffer layer 141 may be formed only in an area where the lower substrate 111 overlaps the plurality of second plate patterns 123. As described above, the buffer layer 141 may be formed of an inorganic material. Thus, the buffer layer 141 may be easily damaged, such as easily cracked, while the display device 100 is stretched. Therefore, in the non-active area AA, the buffer layer 141 may not be formed in areas between the plurality of second plate patterns 123. The buffer layer 141 may be patterned into shapes of the plurality of second plate patterns 123 and formed only on upper portions of the plurality of second plate patterns 123.

In this manner, the buffer layer 141 may be formed only in areas where the lower substrate 111 overlaps the plurality of first plate patterns 121 and the plurality of second plate patterns 123. As described above, since the buffer layer 141 may be formed of an inorganic material, it may be easily damaged, such as being easily cracked, while the display device 100 is stretched. Accordingly, the buffer layer 141 may not be formed in areas between the plurality of first plate patterns 121 and the plurality of second plate patterns 123. The buffer layer 141 may be patterned in shapes of the plurality of first plate patterns 121 and the plurality of second plate patterns 123 and formed only on upper portions of the plurality of first plate patterns 121 and the plurality of second plate patterns 123. Accordingly, in the display device 100 according to an exemplary embodiment of the present disclosure, the buffer layer 141 is formed only in the area where the buffer layer 141 overlaps the plurality of first plate patterns 121 and the plurality of second plate patterns 123 which are rigid substrates, so that damage to various components of the display device 100 may be prevented even when the display device 100 is deformed, such as being bent or stretched.

Referring to FIG. 3, the switching transistor 150 including a gate electrode 151, an active layer 152, a source electrode 153, and a drain electrode 154, and the driving transistor 160 including a gate electrode 161, an active layer 162, a source electrode, and a drain electrode 164 are formed on the buffer layer 141.

First, referring to FIG. 3, the active layer 152 of the switching transistor 150 and the active layer 162 of the driving transistor 160 are disposed on the buffer layer 141. For example, each of the active layer 152 of the switching transistor 150 and the active layer 162 of the driving transistor 160 may be formed of an oxide semiconductor. Alternatively, the active layer 152 of the switching transistor 150 and the active layer 162 of the driving transistor 160 may be formed of amorphous silicon (a-Si), polycrystalline silicon (poly-Si), an organic semiconductor or the like.

The gate insulating layer 142 is disposed on the active layer 152 of the switching transistor 150 and the active layer 162 of the driving transistor 160. The gate insulating layer 142 is configured to electrically insulate the gate electrode 151 of the switching transistor 150 from the active layer 152 of the switching transistor 150 and electrically insulate the gate electrode 161 of the driving transistor 160 from the active layer 162 of the driving transistor 160. Further, the gate insulating layer 142 may be formed of an insulating material. For example, the gate insulating layer 142 may be formed as a single layer of silicon nitride (SiNx) or silicon oxide (SiOx) or multiple layers of silicon nitride (SiNx) or silicon oxide (SiOx), but is not limited thereto.

The gate electrode 151 of the switching transistor 150 and the gate electrode 161 of the driving transistor 160 are disposed on the gate insulating layer 142. The gate electrode 151 of the switching transistor 150 and the gate electrode 161 of the driving transistor 160 are disposed to be spaced apart from each other on the gate insulating layer 142. Further, the gate electrode 151 of the switching transistor 150 overlaps the active layer 152 of the switching transistor 150, and the gate electrode 161 of the driving transistor 160 overlaps the active layer 162 of the driving transistor 160.

Each of the gate electrode 151 of the switching transistor 150 and the gate electrode 161 of the driving transistor 160 may be formed of any one of various metal materials, for example, molybdenum (Mo), aluminum (Al), chromium (Cr), gold (Au), titanium (Ti), nickel (Ni), neodymium (Nd) and copper (Cu), or an alloy of two or more of them, or multiple layers thereof, but the present disclosure is not limited thereto.

The first interlayer insulating layer 143 is disposed on the gate electrode 151 of the switching transistor 150 and the gate electrode 161 of the driving transistor 160. The first interlayer insulating layer 143 insulates the gate electrode 161 of the driving transistor 160 and an intermediate metal layer IM. The first interlayer insulating layer 143 may also be formed of an inorganic material like the buffer layer 141. For example, the first interlayer insulating layer 143 may be formed as a single layer of silicon nitride (SiNx) or silicon oxide (SiOx) or multiple layers of silicon nitride (SiNx) or silicon oxide (SiOx), but is not limited thereto.

The intermediate metal layer IM is disposed on the first interlayer insulating layer 143. Further, the intermediate metal layer IM overlaps the gate electrode 161 of the driving transistor 160. Thus, a storage capacitor is formed in an area where the intermediate metal layer IM overlaps the gate electrode 161 of the driving transistor 160. Specifically, the gate electrode 161 of the driving transistor 160, the first interlayer insulating layer 143 and the intermediate metal layer IM form the storage capacitor. However, an area where the intermediate metal layer IM is disposed is not limited thereto. The intermediate metal layer IM may overlap another electrode to form a storage capacitor in various ways.

The intermediate metal layer IM may be formed of any one of various metal materials, for example, molybdenum (Mo), aluminum (Al), chromium (Cr), gold (Au), titanium (Ti), nickel (Ni), neodymium (Nd) and copper (Cu), or an alloy of two or more of them, or multiple layers thereof, but the present disclosure is not limited thereto.

The second interlayer insulating layer 144 is disposed on the intermediate metal layer IM. The second interlayer insulating layer 144 insulates the gate electrode 151 of the switching transistor 150 from the source electrode 153 and the drain electrode 154 of the switching transistor 150. Also, the second interlayer insulating layer 144 insulates the intermediate metal layer IM from the source electrode and the drain electrode 164 of the driving transistor 160. The second interlayer insulating layer 144 may also be formed of an inorganic material like the buffer layer 141. For example, the second interlayer insulating layer 144 may be formed as a single layer of silicon nitride (SiNx) or silicon oxide (SiOx) or multiple layers of silicon nitride (SiNx) or silicon oxide (SiOx), but is not limited thereto.

The source electrode 153 and the drain electrode 154 of the switching transistor 150 are disposed on the second interlayer insulating layer 144. Also, the source electrode and the drain electrode 164 of the driving transistor 160 are disposed on the second interlayer insulating layer 144. The source electrode 153 and the drain electrode 154 of the switching transistor 150 are disposed to be spaced apart from each other on the same layer. Further, although FIG. 3 does not illustrate the source electrode of the driving transistor 160, the source electrode of the driving transistor 160 is also disposed to be spaced apart from the drain electrode 164 of the driving transistor 160 on the same layer. In the switching transistor 150, the source electrode 153 and the drain electrode 154 may be electrically connected to the active layer 152 to be in contact with the active layer 152. Also, in the driving transistor 160, the source electrode and the drain electrode 164 may be electrically connected to the active layer 162 to be in contact with the active layer 162. Further, the drain electrode 154 of the switching transistor 150 may be electrically connected to the gate electrode 161 of the driving transistor 160 to be in contact with the gate electrode 161 of the driving transistor 160 through a contact hole.

The source electrode 153 and the drain electrodes 154 and 164 may be formed of any one of various metal materials, for example, molybdenum (Mo), aluminum (Al), chromium (Cr), gold (Au), titanium (Ti), nickel (Ni), neodymium (Nd) and copper (Cu), or an alloy of two or more of them, or multiple layers thereof, but the present disclosure is not limited thereto.

Further, in the present disclosure, the driving transistor 160 has been described as having a coplanar structure, but various types of transistors having a staggered structure or the like may also be used.

A gate pad GP and a data pad DP may be disposed on the second interlayer insulating layer 144.

Specifically, referring to FIG. 4, the gate pad GP serves to transfer a gate voltage to the plurality of sub-pixels SPX. The gate pad GP is connected to the first pixel connection line 181 through a contact hole CH. In addition, the gate voltage supplied from the first pixel connection line 181 may be transferred from the gate pad GP to the gate electrode 151 of the switching transistor 150 through a line formed on the first plate pattern 121.

In addition, the data pad DP is a pad to transfer a data voltage to the plurality of sub-pixels SPX. The data pad DP is connected to the second pixel connection line 182 through a contact hole CH. In addition, the data voltage supplied from the second pixel connection line 182 may be transferred from the data pad DP to the source electrode 153 of the switching transistor 150 through a line formed on the first plate pattern 121.

The gate pad GP and the data pad DP may be formed of the same material as the source electrode 153 and the drain electrodes 154 and 164, but are not limited thereto.

Referring to FIG. 3, the passivation layer 145 is formed on the switching transistor 150 and the driving transistor 160. That is, the passivation layer 145 covers the switching transistor 150 and the driving transistor 160 to protect the switching transistor 150 and the driving transistor 160 against permeation of moisture, oxygen, and the like. The passivation layer 145 may be formed of an inorganic material and formed as a single layer or a plurality of layers, but is not limited thereto.

Also, the gate insulating layer 142, the first interlayer insulating layer 143, the second interlayer insulating layer 144 and the passivation layer 145 may be patterned and formed only in an area where they overlap the plurality of first plate patterns 121. The gate insulating layer 142, the first interlayer insulating layer 143, the second interlayer insulating layer 144 and the passivation layer 145 may also be formed of an inorganic material like the buffer layer 141. Thus, the gate insulating layer 142, the first interlayer insulating layer 143, the second interlayer insulating layer 144 and the passivation layer 145 may be easily damaged, such as easily cracked, while the display device 100 is stretched. Therefore, the gate insulating layer 142, the first interlayer insulating layer 143, the second interlayer insulating layer 144 and the passivation layer 145 may not be formed in areas between the plurality of first plate patterns 121 and may be patterned into the shapes of the plurality of first plate patterns 121 and formed only on upper portions of the plurality of first plate patterns 121.

A planarization layer 146 is formed on the passivation layer 145. The planarization layer 146 serves to flatten upper portions of the switching transistor 150 and the driving transistor 160. The planarization layer 146 may be formed as a single layer or a plurality of layers and may be formed of an organic material. Thus, the planarization layer 146 may also be referred to as an organic insulating layer. For example, the planarization layer 146 may be formed of an acrylic-based organic material, but is not limited thereto.

Referring to FIG. 3, the planarization layer 146 may be disposed on the plurality of first plate patterns 121 so as to cover upper surfaces and side surfaces of the buffer layer 141, the gate insulating layer 142, the first interlayer insulating layer 143, the second interlayer insulating layer 144 and the passivation layer 145. In addition, the planarization layer 146 surrounds the buffer layer 141, the gate insulating layer 142, the first interlayer insulating layer 143, the second interlayer insulating layer 144 and the passivation layer 145 together with the plurality of first plate patterns 121. Specifically, the planarization layer 146 may be disposed to cover an upper surface and a side surface of the passivation layer 145, a side surface of the first interlayer insulating layer 143, a side surface of the second interlayer insulating layer 144, a side surface of the gate insulating layer 142, a side surface of the buffer layer 141 and a part of upper surfaces of the plurality of first plate patterns 121. Thus, the planarization layer 146 may compensate for steps between the side surfaces of the buffer layer 141, the gate insulating layer 142, the first interlayer insulating layer 143, the second interlayer insulating layer 144, and the passivation layer 145. The planarization layer 146 may enhance adhesion strength between the planarization layer 146 and the pixel connection lines 181 and 182 disposed on side surfaces of the planarization layer 146.

Referring to FIG. 3, an incline angle of the side surface of the planarization layer 146 may be less than those of the side surfaces of the buffer layer 141, the gate insulating layer 142, the first interlayer insulating layer 143, the second interlayer insulating layer 144 and the passivation layer 145. For example, the side surface of the planarization layer 146 may have a gentle incline than the side surface of the passivation layer 145, the side surface of the first interlayer insulating layer 143, the side surface of the second interlayer insulating layer 144, the side surface of the gate insulating layer 142 and the side surface of the buffer layer 141. Thus, the pixel connection lines 181 and 182 in contact with the side surfaces of the planarization layer 146 are disposed to have a gentle incline. Therefore, when the display device 100 is stretched, a stress generated in the pixel connection lines 181 and 182 may be reduced. Also, it is possible to suppress cracks in the pixel connection lines 181 and 182 or peeling of the pixel connection lines 181 and 182 from the side surface of the planarization layer 146.

Referring to FIGS. 2 to 4, the pixel connection lines 181 and 182 refer to lines that electrically connect the pads disposed on the plurality of first plate patterns 121. The pixel connection lines 181 and 182 are disposed on the plurality of first line patterns 122. The pixel connection lines 181 and 182 may also extend on the plurality of first plate patterns 121 to be electrically connected to the gate pad GP and the data pad DP on the plurality of first plate patterns 121. Also, referring to FIG. 5, the first line pattern 122 is not disposed in an area between the plurality of first plate patterns 121, in which the pixel connection lines 181 and 182 are not disposed.

The pixel connection lines 181 and 182 include the first pixel connection lines 181 and the second pixel connection lines 182. The first pixel connection lines 181 and the second pixel connection lines 182 are disposed between the plurality of first plate patterns 121. Specifically, the first pixel connection lines 181 refer to lines extended in an X-axis direction X between the plurality of first plate patterns 121 among the pixel connection lines 181 and 182. The second pixel connection lines 182 refer to lines extended in a Y-axis direction between the plurality of first plate patterns 121 among the pixel connection lines 181 and 182.

The pixel connection lines 181 and 182 may be formed of a metal material such as copper (Cu), aluminum (Al), titanium (Ti) or molybdenum (Mo), or the pixel connection lines 181 and 182 may have a laminated structure of metal materials such as copper/molybdenum-titanium (Cu/MoTi), titanium/aluminum/titanium (Ti/Al/Ti), or the like, but are not limited thereto.

In a general display device, various lines such as a plurality of gate lines and a plurality of data lines are extended in a shape of straight lines and disposed between a plurality of sub-pixels, and the plurality of sub-pixels are connected to a single signal line. Therefore, in the general display device, various lines such as a gate line, a data line, a high potential power line and a reference voltage line are continuously extended on a substrate from one side to the other side of an organic light emitting display device.

Unlike this, in the display device 100 according to an exemplary embodiment of the present disclosure, various lines such as a gate line, a data line, a high potential power line, a reference voltage line, and the like which are formed in a shape of straight lines and considered to be used in a general organic light emitting display device, are disposed only on the plurality of first plate patterns 121 and the plurality of second plate patterns 123. That is, in the display device 100 according to an exemplary embodiment of the present disclosure, lines formed in a shape of straight lines may be disposed only on the plurality of first plate patterns 121 and the plurality of second plate patterns 123.

In the display device 100 according to an exemplary embodiment of the present disclosure, the pads on two adjacent first plate patterns 121 or two adjacent second plate patterns 123 may be connected by the pixel connection lines 181 and 182, so as to connect discontinuous lines on the first plate patterns 121 or the second plate patterns 123. That is, the pixel connection lines 181 and 182 electrically connect the gate pads GP or the data pads DP on the two adjacent first plate patterns 121. Therefore, the display device 100 according to an exemplary embodiment of the present disclosure may include the plurality of pixel connection lines 181 and 182 to electrically connect various lines, such as a gate line, a data line, a high potential power line, a reference voltage line and the like between the plurality of first plate patterns 121 and the plurality of second plate patterns 123. For example, gate lines may be disposed on the plurality of first plate patterns 121 disposed adjacent to each other in the first direction X. Also, the gate pads GP may be disposed on both ends of the gate lines. In this case, a plurality of gate pads GP on the plurality of first plate patterns 121 disposed adjacent to each other in the first direction X may be connected to each other by the first pixel connection lines 181 serving as the gate lines. Therefore, the gate lines disposed on the plurality of first plate patterns 121 and the first pixel connection lines 181 disposed on the second plate patterns 123 may serve as single gate lines. Further, lines, such as an emission signal line, a low potential power line and a high potential power line which are extended in the first direction X among all of various lines that may be included in the display device 100, may also be electrically connected by the first pixel connection lines 181 as described above.

Referring to FIG. 2 and FIG. 4, the first pixel connection lines 181 may connect the gate pads GP on two first plate patterns 121 that are disposed side by side among the gate pads GP on the plurality of first plate patterns 121 disposed adjacent to each other in the first direction X. The first pixel connection line 181 may serve as a gate line, an emission signal line, a high potential power line, or a low potential power line, but is not limited thereto. For example, the first pixel connection line 181 may function as a gate line and electrically connect the gate pads GP on the two first plate patterns 121 disposed side by side in the first direction X. Therefore, as described above, the gate pads GP on the plurality of first plate patterns 121 disposed in the first direction X may be connected by the first pixel connection line 181 serving as a gate line, and one gate voltage may be transferred to the gate pads.

Further, referring to FIG. 3, the second pixel connection lines 182 may connect the data pads DP on two first plate patterns 121 that are disposed side by side among the data pads DP on the plurality of first plate patterns 121 disposed adjacent to each other in the second direction Y. The second pixel connection line 182 may serve as a data line, a high potential power line, a low potential power line or a reference voltage line, but is not limited thereto. For example, the second pixel connection lines 182 may function as data lines, and may electrically connect data lines on two first plate patterns 121 disposed side by side in the second direction Y. Accordingly, as described above, internal lines on the plurality of first plate patterns 121 disposed in the second direction Y may be connected by a plurality of second pixel connection lines 182 serving as the data lines. A single data voltage may be transferred thereto.

As illustrated in FIG. 4, the first pixel connection line 181 may be disposed to be in contact with an upper surface and the side surface of the planarization layer 146 disposed on the first plate pattern 121. In addition, as illustrated in FIG. 3, the second pixel connection line 182 may be disposed to be in contact with the upper surface and the side surface of the planarization layer 146 disposed on the first plate pattern 121, and may be extended to the upper surface of the first line pattern 122.

However, as illustrated in FIG. 5, it is unnecessary to dispose a rigid pattern in an area where the first pixel connection line 181 and the second pixel connection line 182 are not disposed. Thus, the first line pattern 122, which is a rigid pattern, is not disposed under the first pixel connection line 181 and the second pixel connection line 182.

Meanwhile, referring to FIG. 3, a bank 147 is formed on a connection pad CNT, the pixel connection lines 181 and 182 and the planarization layer 146. The bank 147 is a component to distinguish adjacent sub-pixels SPX. The bank 147 is disposed to cover at least parts of the pad PD, the pixel connection lines 181 and 182 and the planarization layer 146. The bank 147 may be formed of an insulating material. Further, the bank 147 may contain a black material. Since the bank 147 contains a black material, the bank 147 serves to hide lines which are visible through the active area AA. The bank 147 may be formed of, for example, a transparent carbon-based mixture. Specifically, the bank 147 may contain carbon black, but the present disclosure is not limited thereto. The bank 147 may also be formed of a transparent insulating material. Also, although a height of the bank 147 is shown to be lower than a height of the light emitting element 170 in FIG. 3, the height of the bank 147 is not limited thereto, and the height of the bank 147 may be equal to the height of the light emitting element 170.

Referring to FIG. 3, the light emitting element 170 is disposed on the connection pad CNT and the first pixel connection line 181. The light emitting element 170 includes an n-type layer 171, an active layer 172, a p-type layer 173, an n-electrode 174 and a p-electrode 175. The light emitting element 170 of the display device 100 according to an exemplary embodiment of the present disclosure has a flip-chip structure in which the n-electrode 174 and the p-electrode 175 are formed on one surface thereof.

The n-type layer 171 may be formed by injecting n-type impurities into gallium nitride (GaN) having excellent crystallinity. The n-type layer 171 may be disposed on a separate base substrate which is formed of a light emitting material.

The active layer 172 is disposed on the n-type layer 171. The active layer 172 is a light emitting layer that emits light in the light emitting element 170 and may be formed of a nitride semiconductor, for example, indium gallium nitride (InGaN). The p-type layer 173 is disposed on the active layer 172. The p-type layer 173 may be formed by injecting p-type impurities into gallium nitride (GaN).

As described above, the light emitting element 170 according to an exemplary embodiment of the present disclosure is manufactured by sequentially laminating the n-type layer 171, the active layer 172, and the p-type layer 173, and then, etching a predetermined portion of the layers to thereby form the n-electrode 174 and the p-electrode 175. In this case, the predetermined portion is a space to separate the n-electrode 174 and the p-electrode 175 from each other and is etched to expose a part of the n-type layer 171. In other words, a surface of the light emitting element 170 on which the n-electrode 174 and the p-electrode 175 are to be disposed may not be flat and may have different levels of height.

In this manner, the n-electrode 174 is disposed in the etched area, and the n-electrode 174 may be formed of a conductive material. In addition, the p-electrode 175 is disposed in a non-etched area, and the p-electrode 175 may also be formed of a conductive material. For example, the n-electrode 174 is disposed on the n-type layer 171 exposed by an etching process, and the p-electrode 175 is disposed on the p-type layer 173. The p-electrode 175 may be formed of the same material as the n-electrode 174.

An adhesive layer AD is disposed on upper surfaces of the connection pad CNT and the first pixel connection line 181 and between the connection pad CNT and the first pixel connection line 181. Thus, the light emitting element 170 may be bonded onto the connection pad CNT and the first pixel connection line 181. In this case, the n-electrode 174 may be disposed on the first pixel connection line 181 and the p-electrode 175 may be disposed on the connection pad CNT.

The adhesive layer AD may be a conductive adhesive layer formed by dispersing conductive balls in an insulating base member. Thus, when heat or pressure is applied to the adhesive layer AD, the conductive balls are electrically connected to have conductive properties in a portion of the adhesive layer AD to which heat or pressure is applied. Also, an area of the adhesive layer AD to which pressure is not applied may have insulating properties. For example, the n-electrode 174 is electrically connected to the first pixel connection line 181 through the adhesive layer AD, and the p-electrode 175 is electrically connected to the connection pad CNT through the adhesive layer AD. After applying the adhesive layer AD onto an upper surface of the first pixel connection line 181 and the connection pad CNT by an inkjet method or the like, the light emitting element 170 may be transferred onto the adhesive layer AD. Then, the light emitting element 170 may be pressed and heated to thereby electrically connect the connection pad CNT to the p-electrode 175 and electrically connect the first pixel connection line 181 to the n-electrode 174. However, other portions of the adhesive layer AD excluding a portion of the adhesive layer AD disposed between the n-electrode 174 and the first pixel connection line 181 and a portion of the adhesive layer AD disposed between the p-electrode 175 and the connection pad CNT have insulating properties. Meanwhile, the adhesive layer AD may be separately disposed on each of the connection pad CNT and the first pixel connection line 181.

Further, the connection pad CNT is electrically connected to the drain electrode 164 of the driving transistor 160 and receives a driving voltage for driving the light emitting element 170 from the driving transistor 160. In addition, a low potential driving voltage for driving the light emitting element 170 is applied to the first pixel connection line 181. Accordingly, when the display device 100 is turned on, different voltage levels that are applied to the connection pad CNT and the first pixel connection line 181 are respectively transferred to the n-electrode 174 and the p-electrode 175, so that the light emitting element 170 emits light.

The upper substrate 112 serves to support various components disposed under the upper substrate 112. Specifically, the upper substrate 112 may be formed by coating and hardening a material for forming the upper substrate 112 on the lower substrate 111 and the first plate patterns 121, and thus, may be disposed to be in contact with the lower substrate 111, the first plate patterns 121, the first line pattern 122 and the pixel connection lines 181 and 182.

The upper substrate 112 may be formed of the same material as the lower substrate 111. For example, the upper substrate 112 may be formed of silicone rubber such as polydimethylsiloxane (PDMS) or an elastomer such as polyurethane (PU), polytetrafluoroethylene (PTFE) or the like. Thus, the upper substrate 112 may have flexibility. However, the materials of the upper substrate 112 are not limited thereto.

Meanwhile, although not illustrated in FIG. 3, a polarizing layer may also be disposed on the upper substrate 112. The polarizing layer polarizes light incident from the outside of the display device 100 and reduces reflection of external light. Further, instead of the polarizing layer, other optical films or the like may be disposed on the upper substrate 112.

In addition, the filling layer 190 that is disposed on an entire surface of the lower substrate 111 and fills a gap between components disposed on the upper substrate 112 and the lower substrate 111 may be disposed. The filling layer 190 may be formed of a curable adhesive. Specifically, a material for forming the filling layer 190 is coated on the entire surface of the lower substrate 111 and then cured, so that the filling layer 190 may be disposed between components disposed on the upper substrate 112 and the lower substrate 111. For example, the filling layer 190 may be an optically clear adhesive (OCA), and may include an acrylic adhesive, a silicone adhesive, and a urethane adhesive.

### Circuit Structure of Active Area

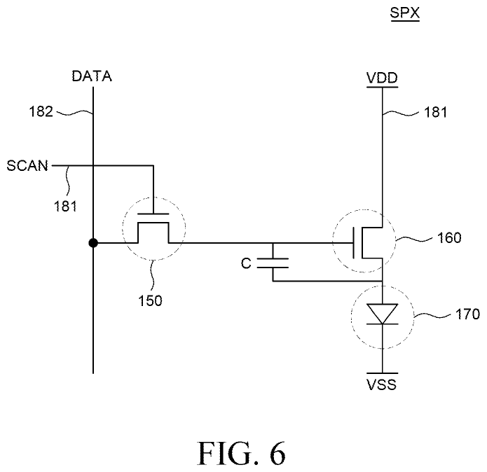

FIG. 6 is a circuit diagram of a sub-pixel of the display device according to an exemplary embodiment of the present disclosure.

Hereinafter, for convenience of explanation, a structure and operations of the sub-pixel SPX of the display device according to an exemplary embodiment of the present disclosure in a case in which the sub-pixel SPX is a 2T (Transistor) 1C (Capacitor) pixel circuit will be described, but the present disclosure is not limited thereto.

Referring to FIGS. 3 and 6, the sub-pixel SPX of the display device according to an exemplary embodiment of the present disclosure may be configured to include the switching transistor 150, the driving transistor 160, a storage capacitor C, and the light emitting element 170.

The switching transistor 150 applies a data signal DATA that is supplied through the second pixel connection line 182 to the driving transistor 160 and the storage capacitor C according to a gate signal SCAN that is supplied through the first pixel connection line 181.

In addition, the gate electrode 151 of the switching transistor 150 is electrically connected to the first pixel connection line 181, the source electrode 153 of the switching transistor 150 is connected to the second pixel connection line 182, and the drain electrode 154 of the switching transistor 150 is connected to the gate electrode 161 of the driving transistor 160.

The driving transistor 160 may operate so that a driving current according to the data voltage DATA and a high potential power VDD supplied through the first pixel connection line 181 can flow in response to the data voltage DATA stored in the storage capacitor C.

In addition, the gate electrode 161 of the driving transistor 160 is electrically connected to the drain electrode 154 of the switching transistor 150, the source electrode of the driving transistor 160 is connected to the first pixel connection line 181, and the drain electrode 164 of the driving transistor 160 is connected to the light emitting element 170.

The light emitting element 170 may operate to emit light according to the driving current that is formed by the driving transistor 160. And, as described above, the n-electrode 174 of the light emitting element 170 may be connected to the first pixel connection line 181 and receive a low potential power VSS, and the p-electrode 175 of the light emitting element 170 may be connected to the drain electrode 164 of the driving transistor 160 and receive a driving voltage corresponding to the driving current.

The sub-pixel SPX of the display device according to an exemplary embodiment of the present disclosure is configured to have a 2T1C structure including the switching transistor 150, the driving transistor 160, the storage capacitor C, and the light emitting element 170, but in a case in which a compensation circuit is added, it may be configured to have various structures such as 3T1C, 4T2C, 5T2C, 6T1C, 6T2C, 7T1C, 7T2C and the like.

As described above, the display device according to an exemplary embodiment of the present disclosure may include a plurality of sub-pixels on a first substrate that is a rigid substrate, and each of the plurality of sub-pixels SPX may be configured to include a switching transistor, a driving transistor, a storage capacitor, and a light emitting element.

Accordingly, the display device according to an exemplary embodiment of the present disclosure can be stretched by a lower substrate and also has a pixel circuit of a 2T1C structure on each first substrate, so that it can emit light depending on a data voltage in accordance with each gate timing.

### Pattern Layer of Non-Active Area

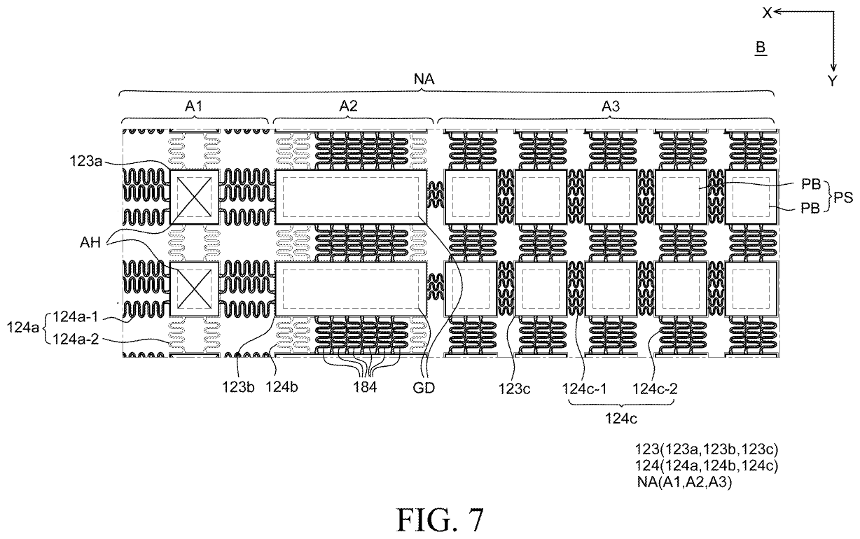

FIG. 7 is an enlarged plan view of a non-active area of the display device according to an exemplary embodiment of the present disclosure.

Specifically, FIG. 7 is an enlarged plan view of region B shown in FIG. 1. For reference, a thin wavy line in FIG. 7 means that only the second line pattern is disposed, and a thick wavy line in FIG. 7 means that a buffer line, a gate connection line or a power line which is the second connection line is disposed on the second line pattern.

As shown in FIG. 7, the non-active area NA includes a first area A1 located outside the active area AA, a second area A2 located outside the first area A1, and a third area A3 located outside the second area A2. For example, the non-active area NA includes a first area A1 disposed adjacent to the active area AA, a second area A2 disposed adjacent to the first area A1, and a third area A3 disposed adjacent to the second area A2. The second area A2 may be disposed between the first area A1 and the third area A3.

In addition, the anchor holes AH are disposed in the first area A1, the gate drivers GD are disposed in the second area A2, and the power blocks PB constituting the power supplies PS are disposed in the third area A3.

That is, the first area A1, the second area A2, and the third area A3 are sequentially positioned outside the active area AA in the first direction X. Accordingly, the anchor holes AH, the gate drivers GD, and the power supplies PS are sequentially disposed in an area adjacent to the active area AA in the first direction X.

The plurality of second plate patterns 123 on which the gate drivers GD and the power supplies PS are formed may be disposed in the non-active area NA. Further, the second line patterns 124 connecting the first plate patterns 121 and the second plate patterns 123 adjacent to each other and connecting the plurality of second plate patterns 123 adjacent to each other are disposed. The second line patterns 124 may be referred to as the second connection patterns. For example, the second line patterns 124 may be disposed between the first plate patterns 121 and the second plate patterns 123 adjacent to each other, and the second line patterns 124 may be disposed between the plurality of second plate patterns 123 adjacent to each other.

Specifically, the plurality of second plate patterns 123 disposed in the non-active area NA include a plurality of first sub-plate patterns 123a located in the first area A1 and having the anchor holes AH disposed therein, a plurality of second sub-plate patterns 123b located in the second area A2 and having the gate drivers GD disposed therein, and a plurality of third sub-plate patterns 123c located in the third area A3 and having the power supplies PS disposed therein.

More specifically, the plurality of first sub-plate patterns 123a are disposed in a column along the second direction Y in the first area A1 on one side of the non-active area NA, the plurality of second sub-plate patterns 123b are disposed in a column along the second direction Y in the second area A2, and the plurality of third sub-plate patterns 123c are disposed in a plurality of columns along the second direction Y in the third area A3.

For example, the plurality of first sub-plate patterns 123a may be disposed in the first area A1 and spaced apart from each other only in the second direction Y, the plurality of second sub-plate patterns 123b may be disposed in the second area A2 and spaced apart from each other only in the second direction Y, and the plurality of third sub-plate patterns 123c may be disposed in the third area A3 and spaced apart from each other in the first direction X and the second direction Y.

Also, sizes of the plurality of first sub-plate patterns 123a may be smaller than those of the plurality of second sub-plate patterns 123b. Specifically, the size of each of the plurality of first sub-plate patterns 123a may be smaller than the size of each of the plurality of second sub-plate patterns 123b. As described above, the anchor holes AH may be disposed in each of the plurality of first sub-plate patterns 123a. An area of the anchor holes AH disposed in the plurality of first sub-plate patterns 123a may be smaller than an area of the gate drivers GD disposed on the plurality of second sub-plate patterns 123b.

Further, the plurality of second line patterns 124 disposed in the non-active area NA include first sub-line patterns 124a located in the first area A1, second sub-line patterns 124b located in the second area A2, and third sub-line patterns 124c located in the third area A3.

The first sub-line patterns 124a may connect the first plate patterns 121 disposed in the active area AA and the first sub-plate patterns 123a of the second plate patterns 123 disposed in the non-active area NA. Also, the first sub-line patterns 124a connect the first sub-plate patterns 123a and the second sub-plate patterns 123b disposed in the non-active area NA.

More specifically, the first sub-line patterns 124a may include 1-1 sub-line patterns 124a-1 and 1-2 sub-line patterns 124a-2. The 1-1 sub-line patterns 124a-1 may extend in the first direction X and connect the first plate patterns 121 and the first sub-plate patterns 123a and connect the first sub-plate patterns 123a and the second sub-plate patterns 123b. Further, the 1-2 sub-line patterns 124a-2 may extend in the second direction Y and connect the 1-1 sub-line patterns 124a-1 and the plurality of first sub-plate patterns 123a adjacent to each other.

The second sub-line patterns 124b extend in the second direction Y and connect the plurality of second sub-plate patterns 123b.

Also, the third sub-line patterns 124c include 3-1 sub-line patterns 124c-1 and 3-2 sub-line patterns 124c-2. The 3-1 sub-line patterns 124c-1 may extend in the first direction X and connect the third sub-plate patterns 123c spaced apart in the first direction X. The 3-2 sub-line patterns 124c-2 may extend in the second direction Y and connect the plurality of third sub-plate patterns 123c spaced apart in the second direction Y.

Meanwhile, a plurality of gate connection lines 184 may be disposed on the second sub-line patterns 124b disposed in the second area A2 to electrically connect a plurality of the gate drivers GD. That is, a gate driving voltage and a gate clock voltage are applied to the plurality of gate connection lines 184 disposed on the second sub-line patterns 124b, so that each of the plurality of gate drivers GD can output a gate voltage. Although it is illustrated in FIG. 7 that the gate connection lines 184 are disposed only in some of a plurality of the second sub-line patterns 124b, the present disclosure is not limited thereto. The gate connection lines 184 may be disposed on all of the plurality of second sub-line patterns 124b.

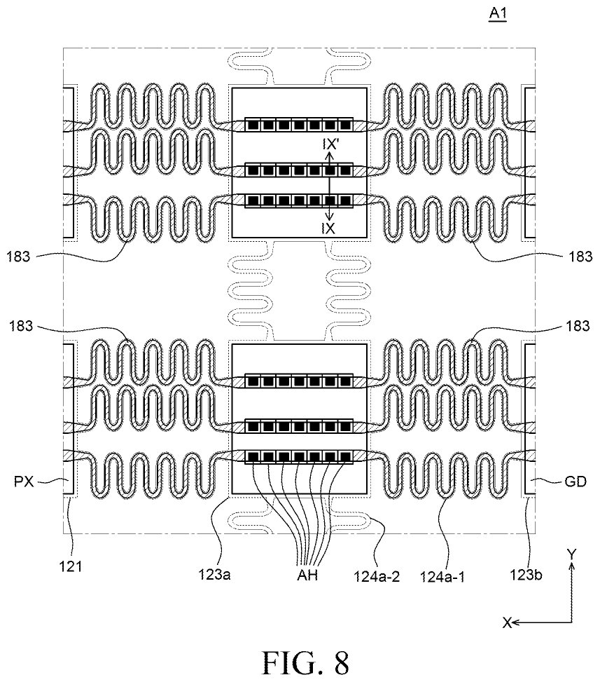

In addition, the gate connection lines 184 formed on the second sub-line patterns 124b may have the same shape as that of the second sub-line patterns 124b. Specifically, each of the plurality of gate connection lines 184 may have a wavy shape. For example, each of the plurality of gate connection lines 184 may have a sine wave shape. However, the shape of each of the plurality of gate connection lines 184 is not limited thereto. For example, each of the plurality of gate connection lines 184 may extend in a zigzag manner and may have various shapes, such as shapes in which a plurality of rhombus-shaped substrates are extended by being connected at vertices thereof. The number and shape of the plurality of gate connection lines 184 illustrated in FIG. 8 are exemplarily provided, and the number and shape of each of the plurality of gate connection lines 184 may be variously changed according to design.

However, in FIG. 7, the gate connection lines 184 are not disposed on all the second sub-line patterns 124b, and the second sub-line patterns 124b on which the gate connection lines 184 are not disposed may also exist. The aforementioned second sub-line patterns 124b on which the gate connection lines 184 are not disposed may be structures that are additionally disposed to secure rigidity against stretching in the second direction Y.

### Configuration of First Area

FIG. 8 is an enlarged plan view of a first area of the display device according to an exemplary embodiment of the present disclosure.

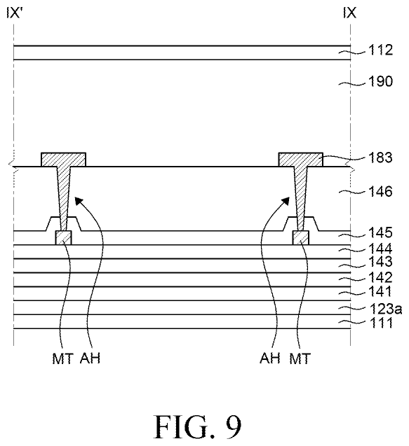

FIG. 9 is a cross-sectional view taken along cutting line IX-IX′ shown in FIG. 8.

As shown in FIG. 8, buffer lines 183, which are lines connecting the gate drivers GD and the plurality of pixels PX, are disposed in the first area A1. The anchor holes AH for fixing the buffer lines 183 may be disposed in the first area A1. For example, the buffer lines 183 may be formed on the first sub-line patterns 124a connecting the first plate patterns 121 and the first sub-plate patterns 123a and connect the gate drivers GD disposed on the first sub-plate patterns 123a and the pixels PX disposed on the first plate patterns 121.

Further, referring to FIG. 8, widths of both ends of the 1-1 sub-line patterns 124a-1 positioned between the first plate patterns 121 and the first sub-plate patterns 123a may be greater than widths of central regions of the 1-1 sub-line patterns 124a-1. In addition, widths of both ends of the 1-1 sub-line patterns 124a-1 formed between the first sub-plate patterns 123a and the second sub-plate patterns 123b may be greater than those of central regions thereof.

Accordingly, in the buffer lines 183 formed on the 1-1 sub-line patterns 124a-1, widths of the buffer lines 183 disposed in areas overlapping with the first plate patterns 121, the first sub-plate patterns 123a or the second sub-plate patterns 123b may be greater than widths of the buffer lines 183 disposed in areas overlapping with the 1-1 sub-line patterns 124a-1.

That is, since the widths of the central regions of the buffer lines 183 are relatively thin, the buffer lines 183 may be stretched with less force. Accordingly, a stretching rate of the buffer lines 183 may be improved. Also, since the widths of both ends of the buffer lines 183 are relatively thick, areas where the buffer lines 183 are in contact with and fixed to the first plate patterns 121, the first sub-plate patterns 123a, or the second sub-plate patterns 123b increase. Accordingly, even if the buffer lines 183 are repeatedly stretched, they may not be separated from the first plate patterns 121, the first sub-plate patterns 123a, or the second sub-plate patterns 123b. Thus, stretching reliability of the buffer lines 183 may be improved.

Each of the buffer lines 183 extend in the first direction X to connect the gate drivers GD and the plurality of pixels PX, and the plurality of buffer lines 183 are arranged in the second direction Y.

Also, the plurality of buffer lines 183 are disposed across the first sub-plate patterns 123a and the first sub-line patterns 124a. Specifically, the first sub-line patterns 124a includes the 1-1 sub-line patterns 124a-1 extending in the first direction X and the 1-2 sub-line patterns 124a-2 extending in the second direction Y, but the buffer lines 183 extend only in the first direction X. Accordingly, the buffer lines 183 may be formed on the first sub-plate patterns 123a and the 1-1 sub-line patterns 124a-1. Also, the buffer lines 183 may not be formed on the 1-2 sub-line patterns 124a-2. Also, the buffer lines 183 formed on the 1-1 sub-line patterns 124a-1 may have the same shape as the 1-1 sub-line patterns 124a-1. Specifically, each of the plurality of buffer lines 183 has a wavy shape. For example, each of the plurality of buffer lines 183 may have a sine wave shape. However, the shape of each of the plurality of buffer lines 183 is not limited thereto, and for example, each of the plurality of buffer lines 183 may extend in a zigzag manner and may have various shapes, such as shapes in which a plurality of rhombus-shaped substrates are extended by being connected at vertices thereof. Also, the number and shape of each of the plurality of buffer lines 183 shown in FIG. 8 are exemplarily provided, and the number and shape of each of the plurality of buffer lines 183 may be variously changed according to design.

Also, the buffer lines 183 formed on the first sub-plate patterns 123a may have a shape of straight lines extending in the first direction X. However, the shape of the buffer lines 183 formed on the first sub-plate patterns 123a is not limited thereto and may be a wavy shape as described above. Widths of the buffer lines 183 formed on the first sub-plate patterns 123a may be greater than those of the buffer lines 183 formed on the 1-1 sub-plate patterns 124a-1. Referring to FIG. 8, widths of the 1-1 sub-line patterns 124a-1 may be formed differently. For example, widths of the 1-1 sub-line patterns 124a-1 disposed in an area adjacent to the first sub-plate pattern 123a or the first plate pattern 121 may be greater than widths of the wavy regions of the 1-1 sub-line patterns 124a-1.

Therefore, since portions of the plurality of buffer lines 183 have wavy shapes, the first area A1 of the non-active area NA may be stretched in the first direction X. In addition, since other portions of the plurality of buffer lines 183 have a shape of straight lines, resistance of the buffer lines 183 can be reduced. Accordingly, delay of a gate voltage transmitted through the plurality of buffer lines 183 can be reduced or minimized.

Also, a plurality of the anchor holes AH are formed on the first sub-plate patterns 123a so that the plurality of buffer lines 183 and metal patterns MT disposed on a layer different from that of the plurality of buffer lines 183 come into contact with each other.

As shown in FIG. 8, the plurality of anchor holes AH may be formed to overlap the buffer lines 183 formed on the first sub-plate pattern 123a. Specifically, since the buffer lines 183 formed on the first sub-plate pattern 123a extend in the first direction X, the plurality of anchor holes AH may be disposed in the first direction X along the buffer lines 183 formed on the first sub-plate pattern 123a.

For example, since the plurality of buffer lines 183 extending in the first direction X are arranged in the second direction Y on the first sub-plate pattern 123a, the plurality of anchor holes AH disposed in the first direction X may be arranged in plural in the second direction Y.

Also, referring to FIG. 9, the plurality of buffer lines 183 may directly contact other metal patterns MT through the plurality of respective anchor holes AH.

The buffer layer 141, the gate insulating layer 142, the first interlayer insulating layer 143, the second interlayer insulating layer 144, and the passivation layer 145 which are inorganic insulating layers, and the planarization layer 146 which is an organic insulating layer may be disposed on the first sub-plate pattern 123a disposed on the lower substrate 111.

Further, the buffer lines 183 may be disposed on the planarization layer 146, and the metal patterns MT may be disposed between the buffer layer 141, the gate insulating layer 142, the first interlayer insulating layer 143, the second interlayer insulating layer 144, and the passivation layer 145 which are inorganic insulating layers.

For example, in FIG. 9, the metal pattern MT may be formed of the same material as the source electrode and the drain electrode of the transistor disposed between the second interlayer insulating layer 144 and the passivation layer 145. That is, the metal pattern MT may be formed of the same material as the source electrode and the drain electrode on the same layer as the source electrode and the drain electrode of the transistor.

However, the metal pattern MT is not limited thereto, and the metal pattern MT may be formed of the same material as the intermediate metal layer disposed between the first interlayer insulating layer 143 and the second interlayer insulating layer 144, or the metal pattern MT may be formed of the same material as the gate electrode of the transistor disposed between the gate insulating layer 142 and the first interlayer insulating layer 143.

Also, the filling layer 190 and the upper substrate 112 may be sequentially disposed on the buffer lines 183 and the planarization layer.

As described above, the display device according to an exemplary embodiment of the present disclosure may include the anchor holes AH for fixing the buffer lines. Thus, even if the display device is repeatedly stretched, the buffer lines 183 may not be separated from component thereunder. Also, since the buffer lines 183 are fixed on the first sub-plate pattern 123a through the anchor holes AH, areas where the buffer lines 183 can move flexibly are reduced. Thus, stretching stress applied to the buffer lines 183 can be significantly reduced. As a result, since the anchor holes AH are formed in the display device according to an exemplary embodiment of the present disclosure, stretching reliability of the display device can be stably secured.

Also, when manufacturing the display device, components are disposed on the lower substrate, lifted off, and separated, and then, the filling layer and the upper substrate are attached thereto. As described above, when the components disposed on the lower substrate are lifted off, there occurs a defect in which the buffer lines that are components disposed on the lower substrate, are torn off. Therefore, in the display device according to an exemplary embodiment of the present disclosure, by fixing the buffer lines through the anchor holes, the display device may not be damaged in the case of a lift off operation. As a result, the display device according to an exemplary embodiment of the present disclosure may also promote process stability.

### Configuration of Third Area

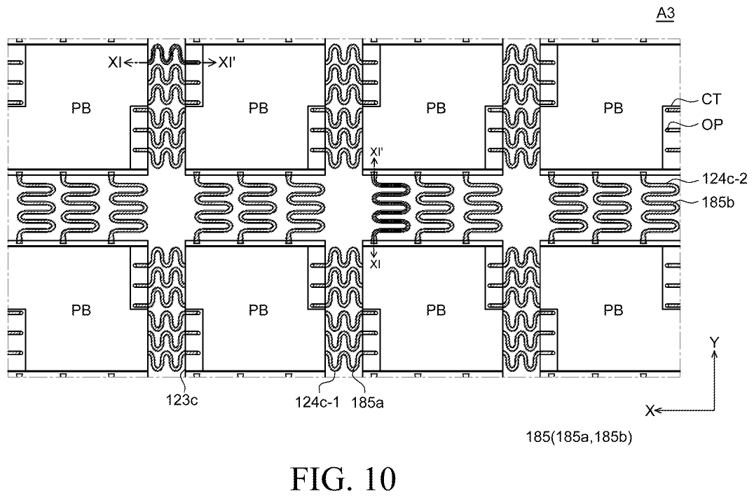

FIG. 10 is an enlarged plan view of a third area of the display device according to an exemplary embodiment of the present disclosure.

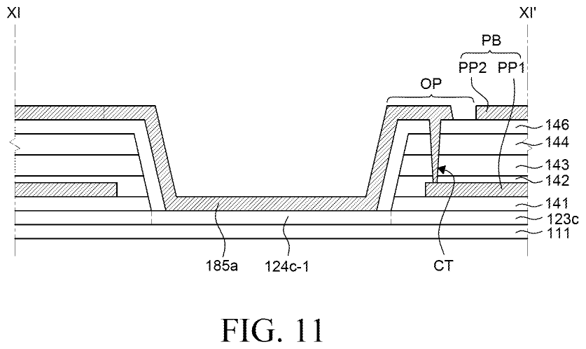

FIGS. 11 to 13 are cross-sectional views taken along cutting line XI-XI′ shown in FIG. 10, and are cross-sectional views taken along the same cutting line for explaining various embodiments.

As shown in FIG. 10, the plurality of power blocks PB constituting the power supplies PS and power lines 185 connecting the plurality of power blocks PB are disposed in the third area A3.

The plurality of power blocks PB are respectively formed on the plurality of third sub-plate patterns 123c spaced apart from each other. As described above, since the third sub-plate patterns 123c may be disposed in the form of islands that are spaced apart from each other in the first direction X and the second direction Y, the plurality of power blocks PB may also be disposed in the form of islands that are spaced apart from each other in the first direction X and the second direction Y.

FIG. 10 shows the plurality of power blocks PB disposed in a matrix form of 4×2 that are disposed in each of the plurality of third sub-plate patterns 123c disposed in a matrix form of 4×2, but the present disclosure is not limited thereto. However, an arrangement form of the plurality of power blocks PB may be variously modified. For example, not only one power block PB is disposed on one third sub-plate pattern 123c, but a plurality of power blocks PB may be disposed in a matrix form.

And, as shown in FIGS. 11 to 13, each of the plurality of power blocks PB may include a plurality of power patterns PP disposed on different layers. Specifically, the plurality of power blocks PB may include a first power pattern PP1 and a second power pattern PP2 formed of at least one plate-shaped electrode that are disposed on different layers.

That is, each of the first power pattern PP1 and the second power pattern PP2 may include at least one plate-shaped electrode. The plate-shaped electrodes of the first power pattern PP1 and the second power pattern PP2 may be insulated by any one insulating layer used for an insulation purpose among the various components constituting the display device 100 described above. The plate-shaped electrodes constituting each of the first power pattern PP1 and the second power pattern PP2 may be electrically connected through interlayer contact holes CTa and CTb in the insulating layers.

The buffer layer 141, the gate insulating layer 142, the first interlayer insulating layer 143, the second interlayer insulating layer 144, and the passivation layer 145 which are inorganic insulating layers or the planarization layer 146 which is an organic insulating layer may be disposed on the third sub-plate pattern 123c disposed on the lower substrate 111.

FIGS. 11 to 13 show the buffer layer 141, the gate insulating layer 142, the first interlayer insulating layer 143, the second interlayer insulating layer 144, and the planarization layer 146 which is an organic insulating layer. However, this to explain that various configurations can be selectively used for the purpose of insulation, and various modifications are possible. For example, the passivation layer 145 may be further included on the second interlayer insulating layer 144, or the layers for the purpose of insulation described above may be deleted or replaced with other configurations having insulating functions.

Hereinafter, various configurations of the power patterns PP1 and PP2 in the power blocks PB that can improve display quality of the display device 100 by reducing or minimizing a drop in driving voltage will be described.

Referring to FIG. 11, the first power pattern PP1 may be disposed between the buffer layer 141, the gate insulating layer 142, the first interlayer insulating layer 143, the second interlayer insulating layer 144, and the passivation layer 145 which are organic insulating layers. Also, the second power pattern PP2 may be disposed on the planarization layer 146.

For example, in FIG. 11, the first power pattern PP1 may be formed of the same material as the source electrode and the drain electrode of the transistor disposed between the buffer layer 141 and the passivation layer 145 or a back shield metal (BSM). That is, the first power pattern PP1 may be formed of the same material as the source electrode and the drain electrode of the transistor or the BSM and on the same layer as the source electrode and the drain electrode of the transistor or the BSM.

However, the first power pattern PP1 is not limited thereto, and the first power pattern PP1 may be formed of the same material as the intermediate metal layer disposed between the first interlayer insulating layer 143 and the second interlayer insulating layer 144. Alternatively, the first power pattern PP1 may be formed of the same material as the gate electrode of the transistor disposed between the gate insulating layer 142 and the first interlayer insulating layer 143.

In addition, although FIG. 11 shows that the power block PB is composed of only two power pattern layers PP1 and PP2, the present disclosure is not limited thereto and the power block PB may be formed of a plurality of power pattern layers disposed on different layers of the power block PB.

Also, although not shown in FIG. 11, the filling layer 190 and the upper substrate 112 may be sequentially disposed on the second power pattern PP2 and the planarization layer.

Meanwhile, as shown in FIG. 10, a plurality of the power lines 185 connect the plurality of power blocks PB disposed in the form of islands to each other.

Accordingly, the plurality of power lines 185 include first power lines 185a extending in the first direction X and second power lines 185b extending in the second direction Y.

Also, the plurality of first power lines 185a extending in the first direction X are disposed on the 3-1 sub-line patterns 124c-1 extending in the first direction X, and the plurality of second power lines 185b extending in the second direction Y are disposed on the 3-2 sub-line patterns 124c-2 extending in the second direction Y.

In addition, the first power line 185a formed on the 3-1 sub-line pattern 124c-1 may have the same shape as the 3-1 sub-line pattern 124c-1, and the second power line 185b formed on the sub-line pattern 124c-2 may have the same shape as the 3-2 sub-line pattern 124c-2. Specifically, each of the plurality of first power lines 185a and the plurality of second power lines 185b have a wavy shape. For example, each of the plurality of first power lines 185a and the plurality of second power lines 185b may have a sine wave shape. However, the shape of each of the plurality of first power lines 185a and the plurality of second power lines 185b is not limited thereto, and for example, each of the plurality of first power lines 185a and the plurality of second power lines 185b may be extended in a zigzag manner, and may have various shapes, such as shapes in which a plurality of rhombus-shaped substrates are extended by being connected at vertices thereof.

In addition, in FIG. 10, six first power lines 185a are connected to adjacent power patterns on different layers, and the second power lines 185b are electrically connected to the power blocks adjacent to each other in the second direction Y in an uppermost layer. The number and shape of each of the plurality of first power lines 185a and the plurality of second power lines 185b shown are exemplarily provided, and the number and shape of each of the plurality of first power lines 185a and the plurality of second power lines 185b may be variously changed according to design.

Further, as shown in FIG. 11, the plurality of first power lines 185a may be adjacent to the second power patterns PP2 of the power blocks PB in the first direction X and may be electrically connected to the power patterns PP1 located on different layers through contact holes CT.

To further explain an electrical connection relationship between the first power pattern PP1 and the second power pattern PP2, different voltages may be applied to the first power pattern PP1 and the second power pattern PP2 on one specific third sub-plate pattern 123c.

For example, a low potential voltage is applied to either one of the first power pattern PP1 or the second power pattern PP2, and a high potential voltage is applied to the other power pattern, while the voltages may be applied alternately through the adjacent power blocks PB.

In this manner, each of a path applied the high-potential voltage and a path applied the low-potential voltage is electrically connected through the power patterns (e.g., the first power pattern PP1 or the second power pattern PP2 included in each power blocks PB), so that the high-potential voltage and the low-potential voltage can be evenly applied to the inactive area NA surrounding the active area AA of the display device 100, respectively. In this case, each of the first power pattern PP1 of a lower layer and the second power pattern PP2 of an upper layer is electrically connected to one of the adjacent power blocks PB, and each of the first power pattern PP1 and the second power pattern PP2 is electrically connected to power pattern of a layer different from itself among the power patterns of the adjacent power block PB, so that resistance capable of occurring in a configuration of electrically connecting the low potential voltage or the high potential voltage is not applied to a specific voltage line.

In order to form the above-described connection relationship, a connection portion OP that opens the planarization layer 146 by the second power pattern PP2 of the uppermost layer is disposed, and the connection portion OP is disposed so that the first power pattern PP1 is electrically connected to the first power line 185a.

The plurality of first power lines 185a electrically connect the second power pattern PP2 of the upper layer and the power pattern PP1 of the lower layer in the power block PB adjacent thereto. In this case, a voltage applied to the upper layer is applied to the power pattern in the lower layer of the power block PB, and a voltage applied to the lower layer is applied to the power pattern in the upper layer of the adjacent power block PB. That is, different voltages applied to the power blocks may cross with and be connected to the upper and lower layers of the adjacent power blocks PB.

Since FIG. 11 is a cut-away cross-sectional view of the first power line 185a, an electrical connection structure of the first power line 185a with the adjacent power block PB will be described.

The first power line 185a may be disposed on the 3-1 sub-line pattern 124c-1 disposed on the lower substrate 111. The first power line 185a may include at least one metal layer, and a metal may be selectively applied in consideration of stretchability. For example, a metal such as copper (Cu) may be disposed.

The first power line 185a is disposed to electrically connect the power patterns PP1 and PP2 of the adjacent power blocks PB. In particular, the second power pattern PP2 disposed on the upper layer is disposed to be electrically connected to the first power pattern PP1 disposed on the lower layer in the adjacent power block PB through the contact hole CT.

Also, the first and second power lines 185a and 185b may be formed of the same material as the second power pattern PP2.

Meanwhile, the first power pattern PP1 may be formed of the same material as the source electrode and the drain electrode of the transistor. However, the first power pattern PP1 is not limited thereto and may be formed of the same material as the intermediate metal layer disposed between the buffer layer 141 and the second interlayer insulating layer 144.

As described above, the first and second power lines 185a and 185b are formed of the same material as the second power pattern PP2, so that electrical connection between the first power pattern PP1 and the second power pattern PP2 may be formed. Accordingly, the low potential driving voltage may be applied to a plurality of the first power patterns PP1 disposed on one side through a link line. The low potential driving voltage applied to the first power pattern PP1 is applied to the second power pattern PP2 adjacent thereto through the first power line 185a, and then, is applied to another first power pattern PP1 adjacent in the first direction X through the first power line 185a. At this time, a voltage applied to a plurality of the second power patterns PP2 disposed on one side through another link line may be a voltage different from the above-described low potential driving voltage, and it may be a high potential driving voltage. The applied high potential driving voltage is applied to the adjacent second power pattern PP2 through the first power line 185a and then is applied to the adjacent first power pattern PP1 again.

In summary, different voltages may be applied to the first and second power patterns PP1 and PP2 in substantially the same block, and alternate voltages may be applied to the adjacent power blocks PB.

As described above, since driving voltages of different voltages are alternately applied to the power patterns in different layers, electrical resistance is not biased to a specific driving voltage to prevent a drop in the specific driving voltage, so that display quality of the display device is further improved.

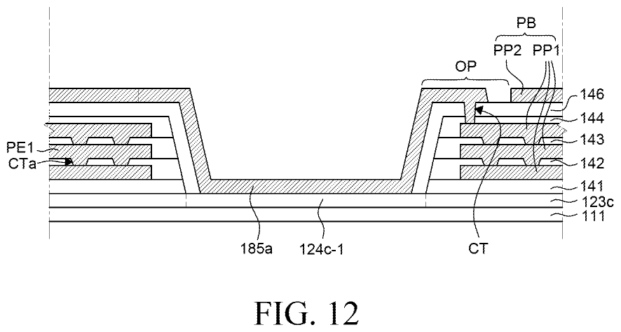

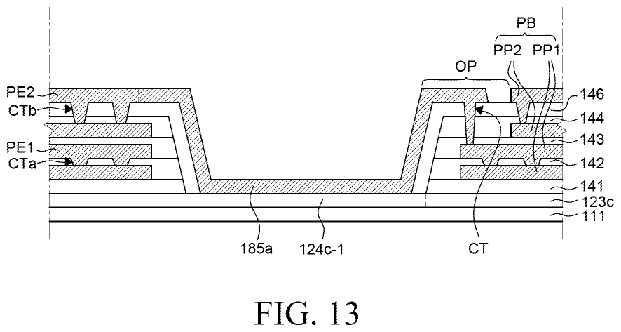

Various deformable embodiments of the present disclosure will be described with reference to FIGS. 12 and 13.

Referring to FIGS. 12 and 13, the first power pattern PP1 and the second power pattern PP2 may include at least one plate-shaped electrode PE.

Referring to FIG. 12 as an example, the first power pattern PP1 includes a plurality of plate-shaped electrodes PE, and the respective plate-shaped electrodes PE may be insulated by the buffer layer 141 and the planarization layer 146 and insulating function layers therebetween. The respective plate-shaped electrodes PE may be electrically connected through interlayer contact holes CTa and CTb.

The interlayer contact holes CTa and CTb electrically connect each of the first power pattern PP1 and the second power pattern PP2, while at least one or more contact holes CTa and CTb are disposed in the insulating function layers that insulate the respective plate-shaped electrodes PE, so that electrical resistance can be further reduced.

The exemplary embodiments of the present disclosure can also be described as follows:

According to an aspect of the present disclosure, there is provided a display device. The display device includes a lower substrate including an active area and a non-active area and configured to be stretchable. The display device further includes a pattern layer disposed on the lower substrate. The pattern layer includes a plurality of first plate patterns and a plurality of first line patterns formed in the active area. The pattern layer includes a plurality of second plate patterns and a plurality of second line patterns formed in the non-active area. The display device further includes a plurality of pixels formed on the plurality of first plate patterns. The display device further includes a plurality of first connection lines connecting the plurality of pixels. The display device further includes gate drivers formed on the plurality of second plate patterns. The display device further includes power supplies formed on the plurality of second plate patterns. The display device further includes a plurality of second connection lines disposed in the non-active area. The display device further includes an upper substrate covering the gate drivers, the power supplies, and the plurality of pixels and configured to be stretchable. The non-active area includes a first area located outside the active area, a second area located outside the first area and having the plurality of gate drivers disposed therein, and a third area located outside the second area and having the plurality of power supplies disposed therein. The plurality of power supplies include a first power pattern and a second power pattern disposed on different layers. Adjacent power supplies among the plurality of power supplies are electrically connected to each other through a power line. Each of the first power pattern and the second power pattern includes at least one plate-shaped electrode.

Each of the first power pattern and the second power pattern may include a plurality of plate-shaped electrodes on different layers.

The plurality of plate-shaped electrodes on the different layers may be electrically connected through interlayer contact holes.

Different voltages may be applied to the first power pattern and the second power pattern on the same second plate pattern.

The second power pattern may further include a connection portion. At least one contact hole may be disposed in the connection portion.

The power line may be electrically connected to the first power pattern through the contact hole and directly connected to the second power pattern adjacent thereto.

The power line may be directly connected to the second power pattern and electrically connected to the first power pattern through the contact hole in the connection portion in the power supply adjacent thereto.

Different voltages may be applied to the first power pattern and the second power pattern adjacent to each other in one direction.

Each of the pixel may include a transistor having a gate electrode, a source electrode, and a drain electrode, and a light emitting element electrically connected to the transistor. The plate-shaped electrode may be formed of the same material as an electrode selected from among the gate electrode, the source electrode, and the drain electrode.

The plurality of respective plate-shaped electrodes on the different layers may be electrically connected by the interlayer contact holes in an insulating layer selected from among a buffer layer, an interlayer insulating layer, a passivation layer, and a planarization layer on the lower substrate.

According to another aspect of the present disclosure, there is provided a display device. The display device includes a plurality of first plate patterns on a substrate. The display device further includes a plurality of second plate patterns on the substrate. The display device further includes a plurality of line patterns connected to the second plate patterns. The display device further includes power lines on the line patterns. The display device further includes a first power pattern configured to include at least one layer on the second plate pattern. The display device further includes an insulating layer on the first power pattern. The display device further includes a second power pattern configured to include at least one layer on the insulating layer. The power lines are directly connected to the second power pattern. The second power pattern further includes at least one connection portion that opens the insulating layer. The power lines are electrically connected to the first power pattern through at least one contact hole in the open insulating layer.

A plurality of pixels may be disposed on the first plate patterns. Each of the pixels may include a transistor having a gate electrode, a source electrode, and a drain electrode, and a light emitting element electrically connected to the transistor. The first power patterns may be formed of the same material as an electrode selected from among the gate electrode, the source electrode, and the drain electrode.

The first power patterns may further include a plurality of first plate-shaped electrodes. The plurality of respective first plate-shaped electrodes may be electrically connected through a plurality of interlayer contact holes in the insulating layer.

The second power pattern may further include a plurality of second plate-shaped electrodes. The plurality of respective second plate-shaped electrodes may be electrically connected through a plurality of interlayer contact holes in the insulating layer.

The second plate-shaped electrode on an uppermost layer among the second plate-shaped electrodes may be formed of the same material as the power lines and is directly connected to the power lines.

The plurality of first plate-shaped electrodes and the plurality of second plate-shaped electrodes may be disposed on different layers.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a lower substrate including an active area configured to display an image and a non-active area adjacent to the active area, the lower substrate configured to be stretchable;
a pattern layer disposed on the lower substrate and including a plurality of first plate patterns and a plurality of first line patterns formed in the active area and a plurality of second plate patterns and a plurality of second line patterns formed in the non-active area;
a plurality of pixels formed on the plurality of first plate patterns;
a plurality of first connection lines electrically connecting the plurality of pixels;
gate drivers formed on the plurality of second plate patterns;
power supplies formed on the plurality of second plate patterns;
a plurality of second connection lines disposed in the non-active area; and
an upper substrate opposite the lower substrate, the upper substrate covering the gate drivers, the power supplies, and the plurality of pixels, the upper substrate configured to be stretchable,
wherein the non-active area includes a first area located outside the active area, a second area located outside the first area and having the plurality of gate drivers disposed therein, and a third area located outside the second area and having the plurality of power supplies disposed therein,
wherein each of the power supplies includes a first power pattern and a second power pattern disposed on different layers,
wherein power supplies adjacent to each other are electrically connected through a power line, and
wherein each of the first power pattern and the second power pattern includes at least one plate-shaped electrode.

2. The display device of claim 1, wherein each of the first power pattern and the second power pattern includes a plurality of plate-shaped electrodes on different layers.

3. The display device of claim 2, wherein the plurality of plate-shaped electrodes on the different layers are electrically connected through interlayer contact holes.

4. The display device of claim 1, wherein different voltages are applied to the first power pattern and the second power pattern on the same second plate pattern.

5. The display device of claim 1, wherein the second power pattern further includes a connection portion, and
wherein at least one contact hole is disposed in the connection portion.

6. The display device of claim 5, wherein the power line is electrically connected to the first power pattern through the contact hole and directly connected to the second power pattern adjacent thereto.

7. The display device of claim 5, wherein the power line is directly connected to the second power pattern and electrically connected to the first power pattern through the contact hole in the connection portion in the power supply adjacent thereto.

8. The display device of claim 4, wherein different voltages are applied to the first power pattern and the second power pattern adjacent to each other in one direction.

9. The display device of claim 1, wherein each of the pixels includes a transistor having a gate electrode, a source electrode, and a drain electrode, and a light emitting element electrically connected to the transistor, and
wherein the plate-shaped electrode is formed of a same material as an electrode selected from among the gate electrode, the source electrode, and the drain electrode.

10. The display device of claim 3, wherein the plurality of respective plate-shaped electrodes on the different layers are electrically connected by the interlayer contact holes in an insulating layer selected from among a buffer layer, an interlayer insulating layer, a passivation layer, and a planarization layer on the lower substrate.

11. A display device, comprising:
a plurality of first plate patterns on a stretchable substrate;
a plurality of second plate patterns on the substrate;
a plurality of line patterns electrically connected to the second plate patterns;
power lines on the line patterns;
a first power pattern configured to include at least one layer on the second plate pattern;
an insulating layer on the first power pattern; and
a second power pattern configured to include at least one layer on the insulating layer,
wherein the power lines are directly connected to the second power pattern,
wherein the second power pattern further includes at least one connection portion that opens the insulating layer, and
wherein the power lines are electrically connected to the first power pattern through at least one contact hole in the open insulating layer.

12. The display device of claim 11, wherein a plurality of pixels are disposed on the first plate patterns,
wherein each of the pixels includes a transistor having a gate electrode, a source electrode, and a drain electrode, and a light emitting element electrically connected to the transistor, and
wherein the first power patterns are formed of a same material as an electrode selected from among the gate electrode, the source electrode, and the drain electrode.

13. The display device of claim 11, wherein the first power patterns further include a plurality of first plate-shaped electrodes, and
wherein the plurality of respective first plate-shaped electrodes are electrically connected through a plurality of interlayer contact holes in the insulating layer.

14. The display device of claim 13, wherein the second power pattern further includes a plurality of second plate-shaped electrodes, and
wherein the plurality of respective second plate-shaped electrodes are electrically connected through a plurality of interlayer contact holes in the insulating layer.

15. The display device of claim 14, wherein the second plate-shaped electrode on an uppermost layer among the second plate-shaped electrodes is formed of a same material as the power lines and is directly connected to the power lines.

16. The display device of claim 14, wherein the plurality of first plate-shaped electrodes and the plurality of second plate-shaped electrodes are disposed on different layers.
